(19) United States
(12) Patent Application Publication
(10) Pub. No.: US 2024/0194760 A1
(43) Pub. Date: Jun. 13, 2024

(54) DIELECTRIC GAS SPACER FORMATION FOR REDUCING PARASITIC CAPACITANCE IN A TRANSISTOR INCLUDING NANOSHEET STRUCTURES

(71) Applicant: Taiwan Semiconductor Manufacturing Company, Ltd., Hsinchu (TW)

(72) Inventors: Chih-Hao CHANG, Hsinchu City (TW); Cheng-Yi PENG, Taipei City (TW); Wei-Yang LEE, Taipei City (TW); Chia-Pin LIN, Xinpu Township (TW)

(21) Appl. No.: 18/308,026

(22) Filed: Apr. 27, 2023

Related U.S. Application Data
(60) Provisional application No. 63/386,607, filed on Dec. 8, 2022.

(51) Int. Cl. H01L 29/49; H01L 21/28; H01L 29/06; H01L 29/423; H01L 29/66; H01L 29/775

(52) U.S. Cl. CPC H01L 29/4991; H01L 21/28123; H01L 29/0673; H01L 29/42392; H01L 29/66439; H01L 29/66545; H01L 29/66553; H01L 29/775

(57) ABSTRACT

Some implementations described herein provide a semiconductor device and methods of formation. The semiconductor device includes a gate-all-around transistor having one or more dielectric regions that include or more dielectric gases. The dielectric regions may include a first dielectric region between epitaxial regions (e.g., source/drain regions) and a first portion of a gate structure of the gate-all-around transistor. The dielectric regions may further include a second dielectric region between a contact structure of gate-all-around transistor and a second portion of the gate structure. By including the dielectric regions in the gate-all-around transistor, a parasitic capacitance associated with the gate-all-around transistor may be reduced relative to another gate-all-around transistor not including the dielectric regions.

### CROSS-REFERENCE TO RELATED APPLICATION

This Patent application claims priority to Provisional Patent Application No. 63/386,607, filed on Dec. 8, 2022, and entitled “Dielectric Gas Spacer Formation for Reducing Parasitic Capacitance in a Transistor Including Nanosheet Structures.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example semiconductor device described herein.

FIGS. 3A and 3B are diagrams of an example implementation of a fin formation process described herein.

FIGS. 4A and 4B are diagrams of an example implementation of a shallow trench isolation (STI) process described herein.

FIG. 5 is a diagram of an example implementation of a layer removal process described herein.

FIG. 6 is a diagram of an example implementation of a dummy gate structure formation process described herein.

FIG. 7 is a diagram of an example implementation of a source/drain recess formation process described herein.

FIGS. 8A-8C are diagrams of an example implementation of a dummy lateral spacer formation process describe herein.

FIG. 9 is a diagram of an example implementation of a source/drain region formation process described herein.

FIGS. 10A-10C are diagrams of an example implementation of a replacement gate process described herein.

FIGS. 11A-11D are diagrams of an example implementation of a dielectric region process described herein.

FIG. 12 is a diagram of an example implementation of a source/drain contact structure process described herein.

FIG. 13 is a diagram of example components of one or more devices described herein.

FIG. 14 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, reducing geometric and dimensional properties of a fin field-effect transistor (finFET) may decrease a performance of the finFET. As an example, a likelihood of short channel effects such as drain-induced barrier lowering in a finFET may increase as finFET technology processing nodes decrease. Additionally, or alternatively, a likelihood of electron tunneling and leakage in a finFET may increase as a gate length of the finFET decreases.

Nanostructure transistors (e.g., nanowire transistors, nanosheet transistors, gate-all-around (GAA) transistors, multi-bridge channel transistors, nanoribbon transistors, and/or other types of nanostructure transistors) may overcome one or more of the above-described drawbacks of finFETs. However, nanostructure transistors face fabrication challenges that can cause performance issues and/or device failures.

For example, a semiconductor device may include a GAA transistor. A performance of an integrated circuit of the semiconductor device may be dependent on one or more characteristics of the GAA transistor, such as a parasitic capacitance of the GAA transistor (e.g., in femtofarads per micron, or (fF/μm)). The parasitic capacitance may include multiple components, including a gate to top-of-fin capacitance (C_{of}), a gate to substrate inside channel capacitance (C_{if}), a gate to low-doped drain (LDD) overlap capacitance (Cₒᵥ), a gate to contact capacitance (C_{co}), and/or an inner gate to EPI capacitance (Cᵢₑ). Structures and/or materials may cause a substantial magnitude of the parasitic capacitance (e.g., greater than approximately 10 fF/μm, among other examples) in the GAA transistor to reduce a performance of the integrated circuit (e.g., introduce noise or distortion to a signal, alter a magnitude of the signal, and/or cause timing parameter issues within the integrated circuit, among other examples).

Some implementations described herein provide a semiconductor device and methods of formation. The semiconductor device includes a GAA transistor having one or more dielectric regions that include one or more dielectric gases. The dielectric regions may include a first dielectric region between epitaxial regions (e.g., source/drain regions) and a first portion of a gate structure of the GAA transistor. The dielectric regions may further include a second dielectric region between a contact structure of GAA transistor and a second portion of the gate structure. By including the dielectric regions in the GAA transistor, a parasitic capacitance associated with the GAA transistor may be reduced relative to another GAA transistor not including the dielectric regions.

In this way, a performance of a semiconductor device including the GAA transistor may improve. By improving the performance of the semiconductor device, the semiconductor device may be compatible with a greater number of applications and/or systems during field use. Additionally, or alternatively, a yield of a volume of semiconductor devices including the GAA transistor may improve to improve a manufacturing efficiency of the volume of semiconductor devices (e.g., a utilization of semiconductor processing tools, a consumption of materials, and/or a utilization of supporting computing resources, among other examples).

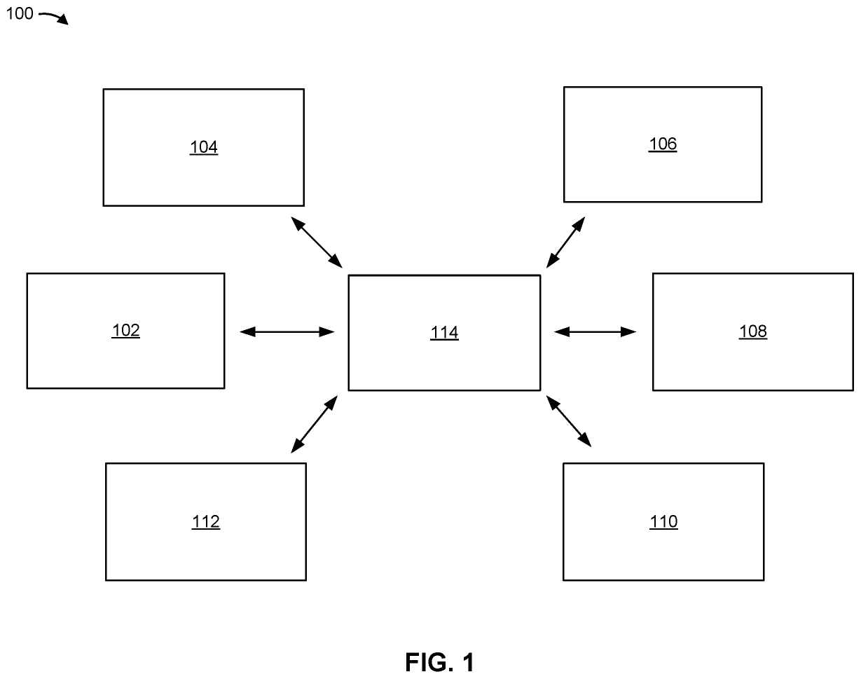

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that can be filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions. In some implementations, the etch tool 108 includes a plasma-based asher to remove a photoresist material and/or another material.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

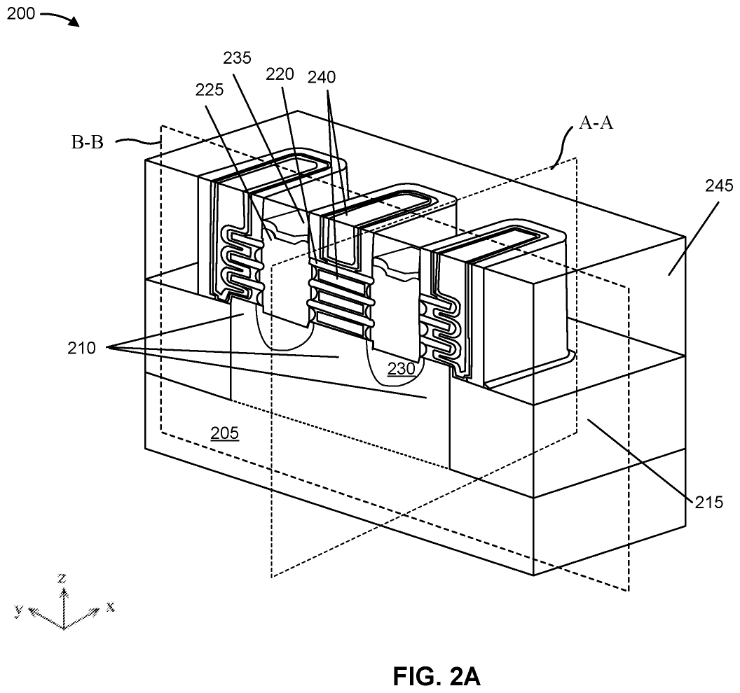

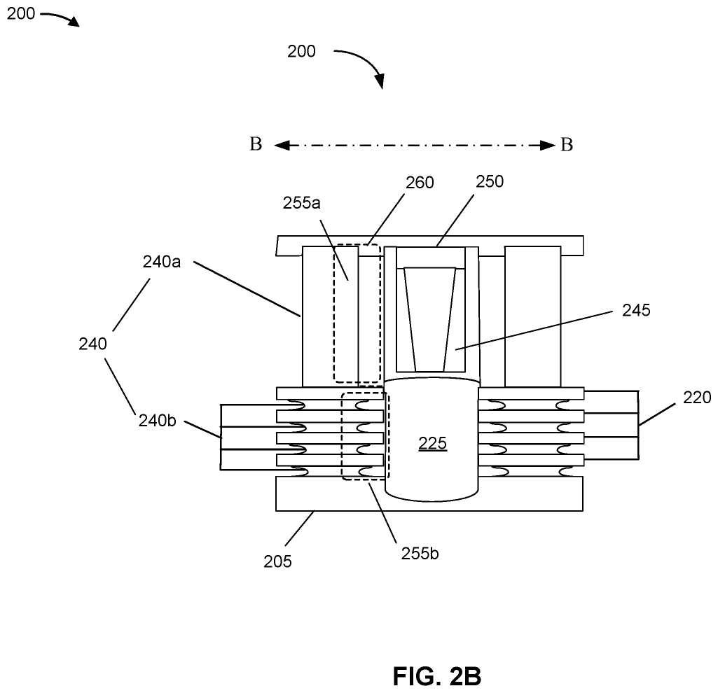

As described in greater detail in connection with FIGS. 2A-14 and elsewhere herein, the semiconductor processing tools 102-112 may perform a combination of operations to form one or more portions of a nanostructure transistor. In some implementations, the combination of operations includes forming, over a semiconductor substrate, a plurality of nanostructure layers in a direction that is perpendicular to the semiconductor substrate, where the plurality of nanostructure layers comprises a plurality of sacrificial layers alternating with a plurality of channel layers. The series of operations includes forming, over the plurality of nanostructure layers, a dummy gate structure. The series of operations includes forming, in each of the plurality of sacrificial layers, a first plurality of lateral cavities that penetrate laterally into respective sacrificial layers of the plurality of sacrificial layers. The series of operations includes forming a dummy inner spacer layer including a first portion and a second portion, where the first portion of the dummy inner spacer layer fills the first plurality of lateral cavities. The series of operations includes removing the second portion of the dummy inner spacer layer, where the first portion that fills the first plurality of lateral cavities remains in the first plurality of lateral cavities, and where the first portion that fills the first plurality of lateral cavities corresponds to a plurality of dummy lateral spacers within the first plurality of lateral cavities. The series of operations includes removing the dummy gate structure. The series of operations includes removing the plurality of sacrificial layers. The series of operations includes forming a metal gate structure, where forming the metal gate structure includes forming a portion that wraps around a plurality of nanostructure channels formed from the plurality of channel layers. The series of operations includes removing the plurality of dummy lateral spacers to form a dielectric region including a second plurality of lateral cavities between the portion of the metal gate structure that wraps around the plurality of nanostructure channels and a source/drain region.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

FIGS. 2A and 2B are diagrams of an example semiconductor device described herein. The semiconductor device includes one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The semiconductor device may include one or more additional devices, structures, and/or layers not shown in FIGS. 2A and 2B. For example, the semiconductor device may include additional layers and/or dies formed on layers above and/or below the portion of the semiconductor device shown in FIGS. 2A and 2B. Additionally, or alternatively, one or more additional semiconductor structures and/or semiconductor devices may be formed in a same layer of an electronic device or integrated circuit (IC) that includes the semiconductor device as the semiconductor device shown in FIGS. 2A and 2B.

As shown in the isometric view of FIG. 2A, a semiconductor device 200 includes a semiconductor substrate 205. The semiconductor substrate 205 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, a silicon carbide (SiC) substrate, or another type of semiconductor substrate. The semiconductor substrate 205 may include various layers, including conductive or insulating layers formed on a semiconductor substrate. The semiconductor substrate 205 may include a compound semiconductor and/or an alloy semiconductor. The semiconductor substrate 205 may include various doping configurations to satisfy one or more design parameters. For example, different doping profiles (e.g., n-wells, p-wells) may be formed on the semiconductor substrate 205 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the semiconductor substrate 205 may include an epitaxial layer (epi-layer), may be strained for performance enhancement, and/or may have other suitable enhancement features. The semiconductor substrate 205 may include a portion of a semiconductor wafer on which other semiconductor devices are formed.

Mesa regions 210 are included above (and/or extend above) the semiconductor substrate 205. A mesa region 210 provides a structure on which nanostructures of the semiconductor device 200 are formed, such as nanostructure channels, nanostructure gate portions that wrap around each of the nanostructure channels, and/or sacrificial nanostructures, among other examples. In some implementations, one or more mesa regions 210 are formed in and/or from a fin structure (e.g., a silicon fin structure) that is formed in the semiconductor substrate 205. The mesa regions 210 may include the same material as the semiconductor substrate 205 and are formed from the semiconductor substrate 205. In some implementations, the mesa regions 210 are doped to form different types of nanostructure transistors, such as p-type nanostructure transistors and/or n-type nanostructure transistors. In some implementations, the mesa regions 210 include silicon (Si) materials or another elementary semiconductor material such as germanium (Ge). In some implementations, the mesa regions 210 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof.

The mesa regions 210 are fabricated by suitable semiconductor process techniques, such as masking, photolithography, and/or etch processes, among other examples. As an example, fin structures may be formed by etching a portion of the semiconductor substrate 205 away to form recesses in the semiconductor substrate 205. The recesses may then be filled with isolating material that is recessed or etched back to form shallow trench isolation (STI) regions 215 above the semiconductor substrate 205 and between the fin structures. Source/drain recesses may be formed in the fin structures, which results in formation of the mesa regions 210 between the source/drain recesses. However, other fabrication techniques for the STI regions 215 and/or for the mesa regions 210 may be used.

The STI regions 215 may electrically isolate adjacent fin structures and may provide a layer on which other layers and/or structures of the semiconductor device 200 are formed. The STI regions 215 may include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. The STI regions 215 may include a multi-layer structure, for example, having one or more liner layers.

The semiconductor device 200 includes a plurality of nanostructure channels 220 that extend between, and are electrically coupled with, source/drain regions 225. Source/drain region(s) may refer to a source or a drain, individually or collectively dependent upon the context. The nanostructure channels 220 are arranged in a direction that is approximately perpendicular to the semiconductor substrate 205. In other words, the nanostructure channels 220 are vertically arranged or stacked above the semiconductor substrate 205.

The nanostructure channels 220 include silicon-based nanostructures (e.g., nanosheets or nanowires, among other examples) that function as the semiconductive channels of the nanostructure transistor(s) of the semiconductor device 200. In some implementations, the nanostructure channels 220 may include silicon germanium (SiGe) or another silicon-based material. The source/drain regions 225 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 200 may include p-type metal-oxide semiconductor (PMOS) nanostructure transistors that include p-type source/drain regions 225, n-type metal-oxide semiconductor (NMOS) nanostructure transistors that include n-type source/drain regions 225, and/or other types of nanostructure transistors.

In some implementations, a buffer region 230 is included under a source/drain region 225 between the source/drain region 225 and a fin structure above the semiconductor substrate 205. A buffer region 230 may provide isolation between a source/drain region 225 and adjacent mesa regions 210. A buffer region 230 may be included to reduce, minimize, and/or prevent electrons from traversing into the mesa regions 210 (e.g., instead of through the nanostructure channels 220, thereby reducing current leakage), and/or may be included to reduce, minimize and/or prevent dopants from the source/drain region 225 into the mesa regions 210 (which reduces short channel effects).

A capping layer 235 may be included over and/or on the source/drain region 225. The capping layer 235 may include silicon, silicon germanium, doped silicon, doped silicon germanium, and/or another material. The capping layer 235 may be included to reduce dopant diffusion and to protect the source/drain regions 225 in semiconductor processing operations for the semiconductor device 200 prior to contact formation. Moreover, the capping layer 235 may contribute to metal-semiconductor (e.g., silicide) alloy formation.

At least a subset of the nanostructure channels 220 extend through one or more gate structures 240. The gate structures 240 may be formed of one or more metal materials, one or more high dielectric constant (high-k) materials, and/or one or more other types of materials. In some implementations, dummy gate structures (e.g., polysilicon (PO) gate structures or another type of gate structures) are formed in the place of (e.g., prior to formation of) the gate structures 240 so that one or more other layers and/or structures of the semiconductor device 200 may be formed prior to formation of the gate structures 240. This reduces and/or prevents damage to the gate structures 240 that would otherwise be caused by the formation of the one or more layers and/or structures. A replacement gate process (RGP) is then performed to remove the dummy gate structures and replace the dummy gate structures with the gate structures 240 (e.g., replacement gate structures).

As further shown in FIG. 2A, portions of a gate structure 240 are formed in between pairs of nanostructure channels 220 in an alternating vertical arrangement. In other words, the semiconductor device 200 includes one or more vertical stacks of alternating nanostructure channels 220 and portions of a gate structure 240, as shown in FIGS. 2A and 2B. In this way, a gate structure 240 wraps around an associated nanostructure channel 220 on all sides of the nanostructure channel 220 which increases control of the nanostructure channel 220, increases drive current for the nanostructure transistor(s) of the semiconductor device 200, and reduces short channel effects (SCEs) for the nanostructure transistor(s) of the semiconductor device 200.

Some source/drain regions 225 and gate structures 240 may be shared between two or more nanoscale transistors of the semiconductor device 200. In these implementations, one or more source/drain regions 225 and a gate structure 240 may be connected or coupled to a plurality of nanostructure channels 220, as shown in the example in FIG. 2A. This enables the plurality of nanostructure channels 220 to be controlled by a single gate structure 240 and a pair of source/drain regions 225.

The semiconductor device 200 may also include an inter-layer dielectric (ILD) layer 245 above the STI regions 215. The Dielectric layer 245 may be referred to as an ILD0 layer. The Dielectric layer 245 surrounds the gate structures 240 to provide electrical isolation and/or insulation between the gate structures 240 and/or the source/drain regions 225, among other examples. Conductive structures such as contacts and/or interconnects may be formed through the Dielectric layer 245 to the source/drain regions 225 and the gate structures 240 to provide control of the source/drain regions 225 and the gate structures 240.

FIG. 2A further shows cross-sectional planes A-A and B-B. The cross-sectional plane A-A (e.g., corresponding to an x-z plane of the semiconductor device 200) may be taken across fin structures of the semiconductor device 200 that include the mesa region 210. The cross-sectional plane B-B (e.g., corresponding to a y-z plane that is perpendicular to the cross-sectional plane A-A) may be taken across portions of the device including the gate structure 240. Cross-sectional views in FIGS. 2B-12B may include cross-sectional views corresponding to the cross-sectional plane A-A and/or the cross-sectional plane B-B.

FIG. 2B shows a side view of an example implementation of the semiconductor device 200. The side view of FIG. 2B corresponds to a side view taken in the cross-sectional plane B-B of FIG. 2A. The implementation of the semiconductor device 200 in FIG. 2B includes additional detailed features than those described in connection with FIG. 2A.

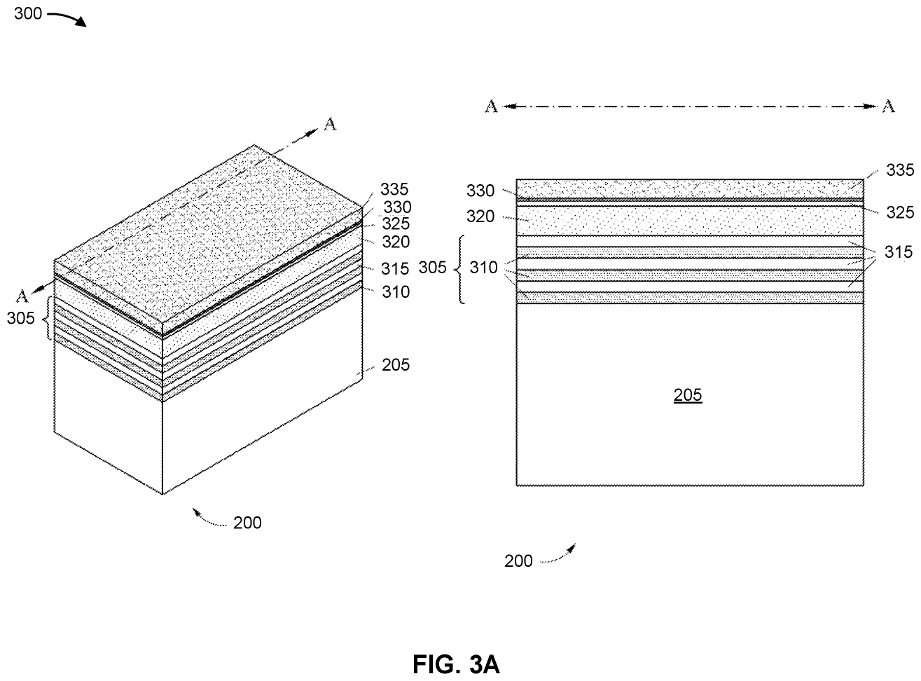

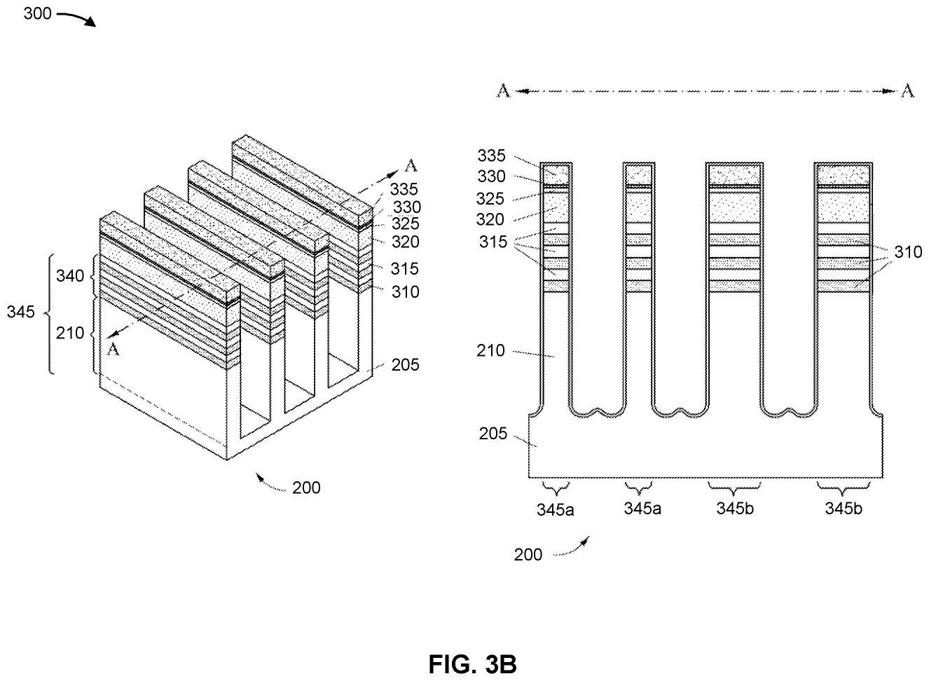

As described in greater detail in connection with FIGS. 3A-12 elsewhere herein, the implementation of the semiconductor device 200 (e.g., a semiconductor device) of FIG. 2B includes the plurality of nanostructure channels 220 over the semiconductor substrate 205, where the plurality of nanostructure channels 220 are arranged in a direction that is perpendicular to the semiconductor substrate 205. The semiconductor device 200 includes the source/drain region 225 adjacent to the plurality of nanostructure channels 220. The semiconductor device 200 includes the gate structure 240 that includes a first portion (e.g., an upper portion 240a) over the plurality of nanostructure channels 220 and a second portion (e.g., a lower portion 240b) wrapping around each of the plurality of nanostructure channels 220. The semiconductor device 200 includes a dielectric region (e.g., a lower dielectric region 255b) between the second portion of the gate structure 240 and the source/drain region 225, where the dielectric region includes a dielectric gas.

Additionally, or alternatively, the semiconductor device 200 includes the plurality of nanostructure channels 220 over the semiconductor substrate 205, where the plurality of nanostructure channels 220 are arranged in a direction that is perpendicular to the semiconductor substrate 205. The semiconductor device 200 includes the source/drain region 225 adjacent to the plurality of nanostructure channels 220. The semiconductor device 200 includes the gate structure 240 that includes a first portion (e.g., the upper portion 240a) over the plurality of nanostructure channels 220 and a second portion (e.g., the lower portion 240b) wrapping around each of the plurality of nanostructure channels 220. The semiconductor device 200 includes a first dielectric region (e.g., an upper dielectric region 255a) between the first portion of the gate structure 240 and a contact structure 250 that is adjacent to the first portion of the gate structure 240, where the first dielectric region includes a first dielectric gas. The semiconductor device 200 includes a second dielectric region (e.g., a lower dielectric region 255b) between the second portion of the gate structure 240 and the source/drain region 225, where the second dielectric region includes a second dielectric gas.

The semiconductor device 200 may further include a filler structure 260. In some implementations, the filler structure 260 is above the upper dielectric region 255a and/or the lower dielectric region 255b. In some implementations, the filler structure 260 is configured to seal a dielectric gas in the upper dielectric region 255a and/or the lower dielectric region 255b.

As indicated above, FIGS. 2A and 2B are provided as examples. Other examples may differ from what is described with regards to FIGS. 2A and 2B.

FIGS. 3A and 3B are diagrams of an example implementation 300 of a fin formation process described herein. The example implementation 300 includes an example of forming fin structures for the semiconductor device 200 or a portion thereof. The semiconductor device 200 may include one or more additional devices, structures, and/or layers not shown in FIGS. 3A and 3B. The semiconductor device 200 may include additional layers and/or dies formed on layers above and/or below the portion of the semiconductor device 200 shown in FIGS. 3A and 3B. Additionally, or alternatively, one or more additional semiconductor structures and/or semiconductor devices may be formed in a same layer of an electronic device that includes the semiconductor device 200.

FIG. 3A illustrates a perspective view of the semiconductor device 200 and a cross-sectional view along the line A-A in the perspective view. As shown in FIGS. 3A, processing of the semiconductor device 200 is performed in connection with the semiconductor substrate 205. A layer stack 305 is formed on the semiconductor substrate 205. The layer stack 305 may be referred to as a superlattice. In some implementations, one or more operations are performed in connection with the semiconductor substrate 205 prior to formation of the layer stack 305. For example, an anti-punch through (APT) implant operation may be performed. The APT implant operation may be performed in one or more regions of the semiconductor substrate 205 above which the nanostructure channels 220 are to be formed. The APT implant operation is performed, for example, to reduce and/or prevent punch-through or unwanted diffusion into the semiconductor substrate 205.

The layer stack 305 includes a plurality of alternating layers that are arranged in a direction that is approximately perpendicular to the semiconductor substrate 205. For example, the layer stack 305 includes vertically alternating layers of first layers 310 and second layers 315 above the semiconductor substrate 205. The quantity of the first layers 310 and the quantity of the second layers 315 illustrated in FIG. 3A are examples, and other quantities of the first layers 310 and the second layers 315 are within the scope of the present disclosure. In some implementations, the first layers 310 and the second layers 315 are formed to different thicknesses. For example, the second layers 315 may be formed to a thickness that is greater relative to a thickness of the first layers 310. In some implementations, the first layers 310 (or a subset thereof) are formed to a thickness in a range of approximately 4 nanometers to approximately 7 nanometers. In some implementations, the second layers 315 (or a subset thereof) are formed to a thickness in a range of approximately 8 nanometers to approximately 12 nanometers. However, other values for the thickness of the first layers 310 and for the thickness of the second layers 315 are within the scope of the present disclosure.

The first layers 310 include a first material composition, and the second layers 315 include a second material composition. In some implementations, the first material composition and the second material composition are the same material composition. In some implementations, the first material composition and the second material composition are different material compositions. As an example, the first layers 310 may include silicon germanium (SiGe) and the second layers 315 may include silicon (Si). In some implementations, the first material composition and the second material composition have different oxidation rates and/or etch selectivity.

As described herein, the second layers 315 may be processed to form the nanostructure channel 220 for subsequently-formed nanostructure transistors of the semiconductor device 200. The first layers 310 are sacrificial nanostructures that are eventually removed and serve to define a vertical distance between adjacent nanostructure channels 220 for a subsequently-formed gate structure 240 of the semiconductor device 200. Accordingly, the first layers 310 are referred to as sacrificial layers and the second layers 315 may be referred to as channel layers.

The deposition tool 102 deposits and/or grows the alternating layers of the layer stack 305 to include nanostructures (e.g., nanosheets) on the semiconductor substrate 205. For example, the deposition tool 102 grows the alternating layers by epitaxial growth. However, other processes may be used to form the alternating layers of the layer stack 305. Epitaxial growth of the alternating layers of the layer stack 305 may be performed by a molecular beam epitaxy (MBE) process, a metalorganic chemical vapor deposition (MOCVD) process, and/or another suitable epitaxial growth process. In some implementations, the epitaxially grown layers such as the second layers 315 include the same material as the material of the semiconductor substrate 205. In some implementations, the first layers 310 and/or the second layers 315 include a material that is different from the material of the semiconductor substrate 205. As described above, in some implementations, the first layers 310 include epitaxially grown silicon germanium (SiGe) layers and the second layers 315 include epitaxially grown silicon (Si) layers. Alternatively, the first layers 310 and/or the second layers 315 may include other materials such as germanium (Ge), a compound semiconductor material such as silicon carbide (SiC), gallium arsenide (GaAs), gallium phosphide (GaP), indium phosphide (InP), indium arsenide (IAs), indium antimonide (InSb), an alloy semiconductor such as silicon germanium (SiGe), gallium arsenide phosphide (GaAsP), aluminum indium arsenide (AlInAs), aluminum gallium arsenide (AlGaAs), indium gallium arsenide (InGaAs), gallium indium phosphide (GaInP), gallium indium arsenide phosphide (GaInAsP), and/or a combination thereof. The material(s) of the first layers 310 and/or the material(s) of the second layers 315 may be chosen based on providing different oxidation properties, different etching selectivity properties, and/or other different properties.

As further shown in FIG. 3A, the deposition tool 102 may form one or more additional layers over and/or on the layer stack 305. For example, a hard mask (HM) layer 320 may be formed over and/or on the layer stack 305 (e.g., on the top-most second layer 315 of the layer stack 305). As another example, a capping layer 325 may be formed over and/or on the hard mask layer 320. As another example, another hard mask layer including an oxide layer 330 and a nitride layer 335 may be formed over and/or on the capping layer 325. The one or more hard mask (HM) layers 320, 325, and 330 may be used to form one or more structures of the semiconductor device 200. The oxide layer 330 may function as an adhesion layer between the layer stack 305 and the nitride layer 335, and may act as an etch stop layer for etching the nitride layer 335. The one or more hard mask layers 320, 325, and 330 may include silicon germanium (SiGe), a silicon nitride (SiₓN_{y}), a silicon oxide (SiOₓ), and/or another material. The capping layer 325 may include silicon (Si) and/or another material. In some implementations, the capping layer 325 is formed of the same material as the semiconductor substrate 205. In some implementations, the one or more additional layers are thermally grown, deposited by CVD, PVD, ALD, and/or are formed using another deposition technique.

FIG. 3B illustrates a perspective view of the semiconductor device 200 and a cross-sectional view along the line A-A. As shown in FIG. 3B, the layer stack 305 and the semiconductor substrate 205 are etched to remove portions of the layer stack 305 and portions of the semiconductor substrate 205. The portions 340 of the layer stack 305, and mesa regions 210 (also referred to as silicon mesas or mesa portions), remaining after the etch operation are referred to a fin structures 345 above the semiconductor substrate 205 of the semiconductor device 200. A fin structure 345 includes a portion 340 of the layer stack 305 over and/or on a mesa region 210 formed in and/or above the semiconductor substrate 205. The fin structures 345 may be formed by any suitable semiconductor processing technique. For example, the deposition tool 102, the exposure tool 104, the developer tool 106, and/or the etch tool 108 may form the fin structures 345 using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures.

In some implementations, the deposition tool 102 forms a photoresist layer over and/or on the hard mask layer including the oxide layer 330 and the nitride layer 335, the exposure tool 104 exposes the photoresist layer to radiation (e.g., deep ultraviolet (UV) radiation, extreme UV (EUV) radiation), a post-exposure bake process is performed (e.g., to remove residual solvents from the photoresist layer), and the developer tool 106 develops the photoresist layer to form a masking element (or pattern) in the photoresist layer. In some implementations, patterning the photoresist layer to form the masking element is performed using an electron beam (e-beam) lithography process. The masking element may then be used to protect portions of the semiconductor substrate 205 and portions the layer stack 305 in an etch operation such that the portions of the semiconductor substrate 205 and portions the layer stack 305 remain non-etched to form the fin structures 345. Unprotected portions of the substrate and unprotected portions of the layer stack 305 are etched (e.g., by the etch tool 108) to form trenches in the semiconductor substrate 205. The etch tool may etch the unprotected portions of the substrate and unprotected portions of the layer stack 305 using a dry etch technique (e.g., reactive ion etching), a wet etch technique, and/or a combination thereof.

In some implementations, another fin formation technique is used to form the fin structures 345. For example, a fin region may be defined (e.g., by mask or isolation regions), and the portions 340 may be epitaxially grown in the form of the fin structures 345. In some implementations, forming the fin structures 345 includes a trim process to decrease the width of the fin structures 345. The trim process may include wet and/or dry etching processes, among other examples.

As further shown in FIG. 3B, fin structures 345 may be formed for different types of nanostructure transistors for the semiconductor device 200. In particular, a first subset of fin structures 345a may be formed for p-type nanostructure transistors (e.g., p-type metal oxide semiconductor (PMOS) nanostructure transistors), and a second subset of fin structures 345b may be formed for n-type nanostructure transistors (e.g., n-type metal oxide semiconductor (NMOS) nanostructure transistors). The second subset of fin structures 345b may be doped with a p-type dopant (e.g., boron (B) and/or germanium (Ge), among other examples) and the first subset of fin structures 345b may be doped with an n-type dopant (e.g., phosphorous (P) and/or arsenic (As), among other examples). Additionally, or alternatively, p-type source/drain regions 225 may be subsequently formed for the p-type nanostructure transistors that include the first subset of fin structures 345a, and n-type source/drain regions 225 may be subsequently formed for the n-type nanostructure transistors that include the second subset of fin structures 345b.

The first subset of fin structures 345a (e.g., PMOS fin structures) and the second subset of fin structures 345b (e.g., NMOS fin structures) may be formed to include similar properties and/or different properties. For example, the first subset of fin structures 345a may be formed to a first height and the second subset of fin structures 345b may be formed to a second height, where the first height and the second height are different heights. As another example, the first subset of fin structures 345a may be formed to a first width and the second subset of fin structures 345b may be formed to a second width, where the first width and the second width are different widths. In the example shown in FIG. 3B, the second width of the second subset of fin structures 345b (e.g., for the NMOS nanostructure transistors) is greater relative to the first width of the first subset of fin structures 345a (e.g., for the PMOS nanostructure transistors). However, other examples are within the scope of the present disclosure.

As indicated above, FIGS. 3A and 3B are provided as an example. Other examples may differ from what is described with regard to FIGS. 3A and 3B. Example implementation 300 may include additional operations, fewer operations, different operations, and/or a different order of operations than those described in connection with FIGS. 3A and 3B.

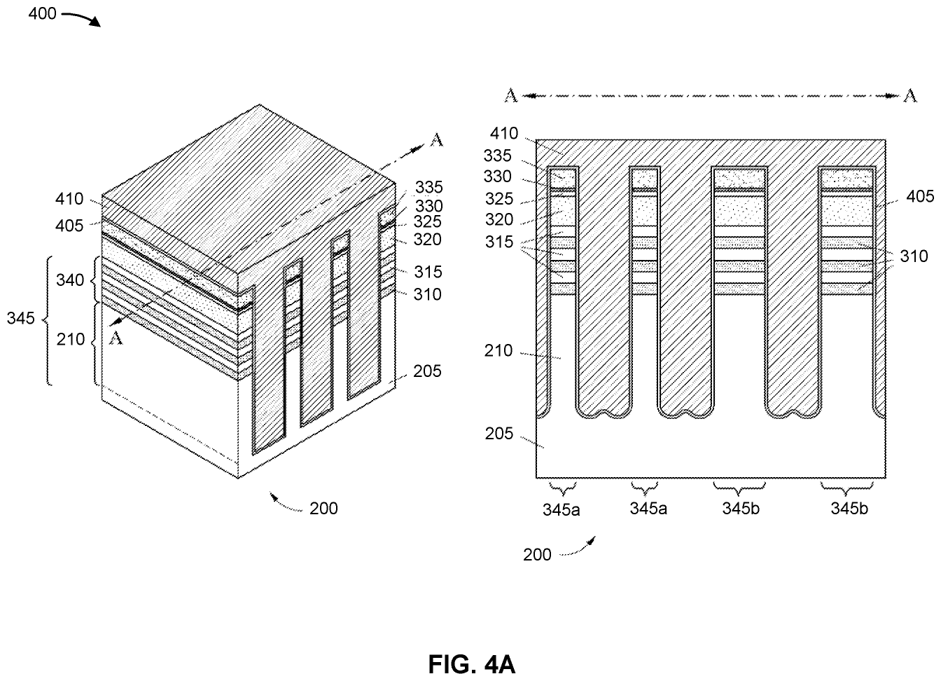

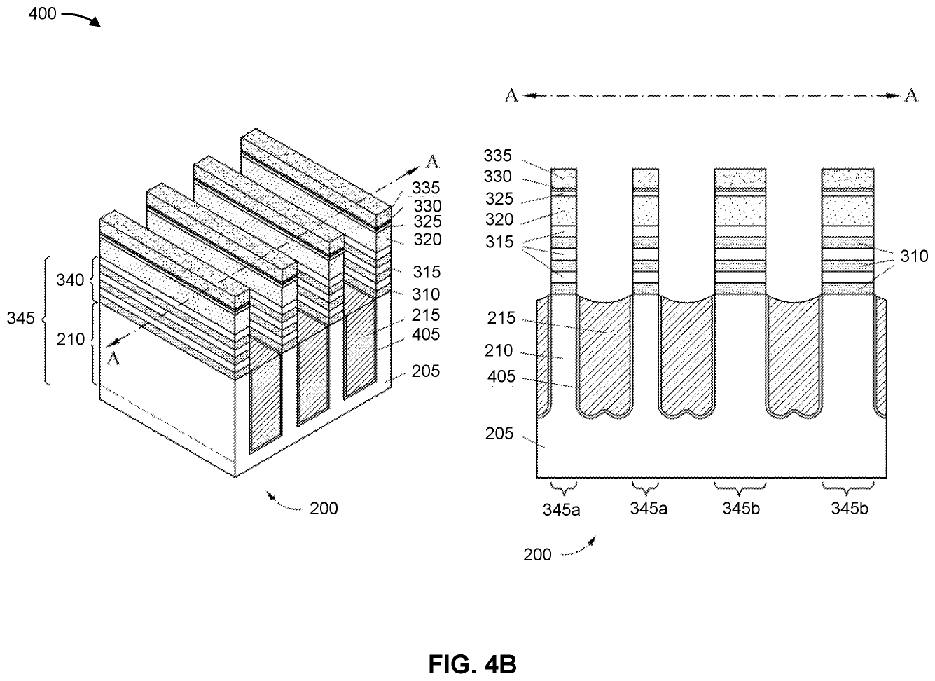

FIGS. 4A and 4B are diagrams of an example implementation 400 of an STI formation process described herein. The example implementation 400 includes an example of forming STI regions 215 between the fin structures 345 for the semiconductor device 200 or a portion thereof. The semiconductor device 200 may include one or more additional devices, structures, and/or layers not shown in FIGS. 3A and 3B. The semiconductor device 200 may include additional layers and/or dies formed on layers above and/or below the portion of the semiconductor device 200 shown in FIGS. 4A and 4B. Additionally, or alternatively, one or more additional semiconductor structures and/or semiconductor devices may be formed in a same layer of an electronic device that includes the semiconductor device 200. In some implementations, the operations described in connection with the example implementation 400 are performed after the processes described in connection with FIGS. 3A and 3B.

FIG. 4A illustrates a perspective view of the semiconductor device 200 and a cross-sectional view along the line A-A. As shown in FIG. 4A, a liner 405 and a dielectric layer 410 are formed above the semiconductor substrate 205 and interposing (e.g., in between) the fin structures 345. The deposition tool 102 may deposit the liner 405 and the dielectric layer 410 over the semiconductor substrate 205 and in the trenches between the fin structures 345. The deposition tool 102 may form the dielectric layer 410 such that a height of a top surface of the dielectric layer 410 and a height of a top surface of the nitride layer 335 are approximately a same height.

Alternatively, the deposition tool 102 may form the dielectric layer 410 such that the height of the top surface of the dielectric layer 410 is greater relative to the height of the top surface of the nitride layer 335, as shown in FIG. 4A. In this way, the trenches between the fin structures 345 are overfilled with the dielectric layer 410 to ensure the trenches are fully filled with the dielectric layer 410. Subsequently, the planarization tool 110 may perform a planarization or polishing operation (e.g., a CMP operation) to planarize the dielectric layer 410. The nitride layer 335 of the hard mask layer may function as a CMP stop layer in the operation. In other words, the planarization tool 110 planarizes the dielectric layer 410 until reaching the nitride layer 335 of the hard mask layer. Accordingly, a height of top surfaces of the dielectric layer 410 and a height of top surfaces of the nitride layer 335 are approximately equal after the operation.

The deposition tool 102 may deposit the liner 405 using a conformal deposition technique. The deposition tool 102 may deposit the dielectric layer using a CVD technique (e.g., a flowable CVD (FCVD) technique or another CVD technique), a PVD technique, an ALD technique, and/or another deposition technique. In some implementations, after deposition of the liner 405, the semiconductor device 200 is annealed, for example, to increase the quality of the liner 405.

The liner 405 and the dielectric layer 410 each includes a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material. In some implementations, the dielectric layer 410 may include a multi-layer structure, for example, having one or more liner layers.

FIG. 4B illustrates a perspective view of the semiconductor device 200 and a cross-sectional view along the line A-A. As shown in FIG. 4B, an etch back operation is performed to remove portions of the liner 405 and portions of the dielectric layer 410 to form the STI regions 215. The etch tool 108 may etch the liner 405 and the dielectric layer 410 in the etch back operation to form the STI regions 215. The etch tool 108 etches the liner 405 and the dielectric layer 410 based on the hard mask layer (e.g., the hard mask layer including the oxide layer 330 and the nitride layer 335). The etch tool 108 etches the liner 405 and the dielectric layer 410 such that the height of the STI regions 215 are less than or approximately a same height as the bottom of the portions 340 of the layer stack 305. Accordingly, the portions 340 of the layer stack 305 extend above the STI regions 215. In some implementations, the liner 405 and the dielectric layer 410 are etched such that the heights of the STI regions 215 are less than heights of top surfaces of the mesa regions 210.

In some implementations, the etch tool 108 uses a plasma-based dry etch technique to etch the liner 405 and the dielectric layer 410. Ammonia (NH₃), hydrofluoric acid (HF), and/or another etchant may be used. The plasma-based dry etch technique may result in a reaction between the etchant(s) and the material of the liner 405 and the dielectric layer 410, including:

SiO₂+4HF→SiF₄+2H₂O

where silicon dioxide (SiO₂) of the liner 405 and the dielectric layer 410 react with hydrofluoric acid to form byproducts including silicon tetrafluoride (SiF₄) and water (H₂O). The silicon tetrafluoride is further broken down by the hydrofluoric acid and ammonia to form an ammonium fluorosilicate ((NH₄)₂SiF₆) byproduct:

SiF₄+2HF+2NH₃→(NH₄)₂SiF₆

The ammonium fluorosilicate byproduct is removed from a processing chamber of the etch tool 108. After removal of the ammonium fluorosilicate, a post-process temperature in a range of approximately 200 degrees Celsius to approximately 250 degrees Celsius is used to sublimate the ammonium fluorosilicate into constituents of silicon tetrafluoride ammonia and hydrofluoric acid.

In some implementations, the etch tool 108 etches the liner 405 and the dielectric layer 410 such that a height of the STI regions 215 between the first subset of fin structures 345a (e.g., for the PMOS nanostructure transistors) is greater relative to a height of the STI regions 215 between the second subset of fin structures 345b (e.g., for the NMOS nanostructure transistors). This primarily occurs due to the greater width the fin structures 345b relative to the width of the fin structures 345a. Moreover, this results in a top surface of an STI region 215 between a fin structure 345a and a fin structure 345b being sloped or slanted (e.g., downward sloped from the fin structure 345a to the fin structure 345b, as shown in the example in FIG. 4A). The etchants used to etch the liner 405 and the dielectric layer 410 first experience physisorption (e.g., a physical bonding to the liner 405 and the dielectric layer 410) as a result of a Van der Waals force between the etchants and the surfaces of the liner 405 and the dielectric layer 410. The etchants become trapped by dipole moment force. The etchants then attach to dangling bonds of the liner 405 and the dielectric layer 410, and chemisorption begins. Here, the chemisorption of the etchant on the surface of the liner 405 and the dielectric layer 410 results in etching of the liner 405 and the dielectric layer 410. The greater width of the trenches between the second subset of fin structures 345a provides a greater surface area for chemisorption to occur, which results in a greater etch rate between the second subset of fin structures 345b. The greater etch rate results in the height of the STI regions 215 between the second subset of fin structures 345b being lesser relative to the height of the STI regions 215 between the first subset of fin structures 345a.

As indicated above, FIGS. 4A and 4B are provided as an example. Other examples may differ from what is described with regard to FIGS. 4A and 4B. Example implementation 400 may include additional operations, fewer operations, different operations, and/or a different order of operations than those described in connection with FIGS. 4A and 4B.

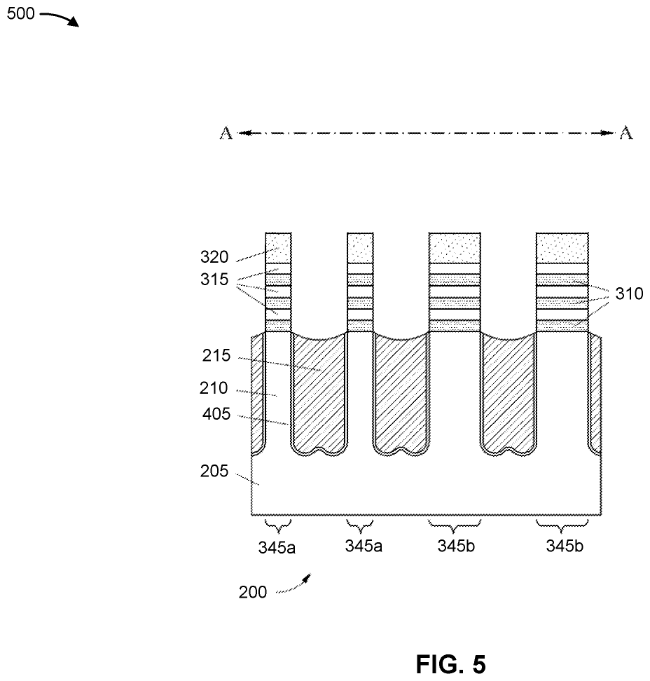

FIG. 5 is an example diagram of an example implementation 500 of a layer removal process described herein. FIG. 5 illustrates a cross-sectional view along the line A-A of FIG. 2A. As shown in FIG. 5, the hard mask layer (including the oxide layer 330 and the nitride layer 335) and the capping layer 325 are removed to expose the hard mask layer 320. In some implementations, the capping layer 325, the oxide layer 330, and the nitride layer 335 are removed using an etch operation (e.g., performed by the etch tool 108), a planarization technique (e.g., performed by the planarization tool 110), and/or another semiconductor processing technique.

As indicated above, FIG. 5 is provided as an example. Other examples may differ from what is described with regard to FIG. 5. Example implementation 500 may include additional operations, fewer operations, different operations, and/or a different order of operations than those described in connection with FIG. 5.

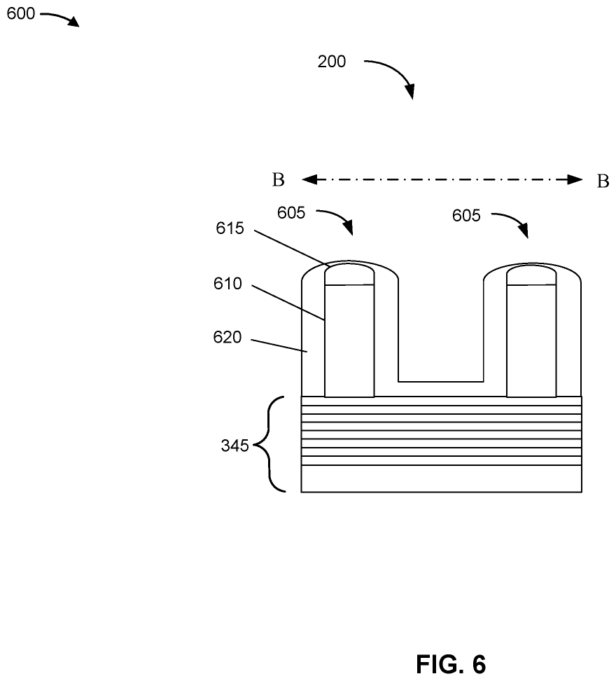

FIG. 6 is a diagram of an example implementation of a dummy gate structure formation process described herein. The example implementation 600 includes an example of forming dummy gate structures for the semiconductor device 200 or a portion thereof. The semiconductor device 200 may include one or more additional devices, structures, and/or layers not shown in FIG. 6. The semiconductor device 200 may include additional layers and/or dies formed on layers above and/or below the portion of the semiconductor device 200 shown in FIG. 6. Additionally, or alternatively, one or more additional semiconductor structures and/or semiconductor devices may be formed in a same layer of an electronic device that includes the semiconductor device 200. In some implementations, the operations described in connection with the example implementation 600 are performed after the processes described in connection with FIGS. 3A-5. FIG. 6 includes a cross-sectional view along the cross-sectional plane B-B of FIG. 2A.

As shown in FIG. 6, dummy gate structures 605 (also referred to as dummy gate stacks or temporary gate structures) are formed over the fin structures 345. The dummy gate structures 605 are sacrificial structures that are to be replaced by replacement gate structures or replacement gate stacks (e.g., the gate structures 240) at a subsequent processing stage for the semiconductor device 200. Portions of the fin structures 345 underlying the dummy gate structures 605 may be referred to as channel regions. The dummy gate structures 605 may also define source/drain (S/D) regions of the fin structures 345, such as the regions of the fin structures 345 adjacent and on opposing sides of the channel regions.

A dummy gate structure 605 may include a gate electrode layer 610, a hard mask layer 615 over and/or on the gate electrode layer 610, and dummy sidewall spacer layers 620 on opposing sides of the gate electrode layer 610 and on opposing sides of the hard mask layer 615. The gate electrode layer 610 includes polycrystalline silicon (polysilicon or PO) or another material. The hard mask layer 615 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The dummy sidewall spacer layers 620 include a silicon oxycarbide (SiOC), a nitrogen free SiOC, or another suitable material.

The dummy sidewall spacer layers 620 may be formed to a thickness that is greater than or approximately equal to 5 nanometers to enable a flow of etchant, that is used to remove dummy lateral spacers for air spacer formation, to propagate downward far enough into the semiconductor device 200 to reach the dummy lateral spacers and remove the dummy lateral spacers.

The layers of the dummy gate structures 605 may be formed using various semiconductor processing techniques such as deposition (e.g., by the deposition tool 102), patterning (e.g., by the exposure tool 104 and the developer tool 106), and/or etching (e.g., by the etch tool 108), among other examples. Examples include CVD, PVD, ALD, thermal oxidation, e-beam evaporation, photolithography, e-beam lithography, photoresist coating (e.g., spin-on coating), soft baking, mask aligning, exposure, post-exposure baking, photoresist developing, rinsing, drying (e.g., spin-drying and/or hard baking), dry etching (e.g., reactive ion etching), and/or wet etching, among other examples.

The dummy sidewall spacer layers 620 may be conformally deposited and etched back such that the dummy sidewall spacer layers 620 remain on the sidewalls of the dummy gate structures 605. In some implementations, the dummy sidewall spacer layers 620 include a plurality of types of spacer layers. For example, the dummy sidewall spacer layers 620 may include a seal spacer layer that is formed on the sidewalls of the dummy gate structures 605 and a bulk spacer layer that is formed on the seal spacer layer. The seal spacer layer and the bulk spacer layer may be formed of similar materials or different materials. In some implementations, the bulk spacer layer is formed without plasma surface treatment that is used for the seal spacer layer. In some implementations, the bulk spacer layer is formed to a greater thickness relative to the thickness of the seal spacer layer.

As indicated above, FIG. 6 are provided as an example. Other examples may differ from what is described with regard to FIG. 6. Example implementation 600 may include additional operations, fewer operations, different operations, and/or a different order of operations than those described in connection with FIG. 6.

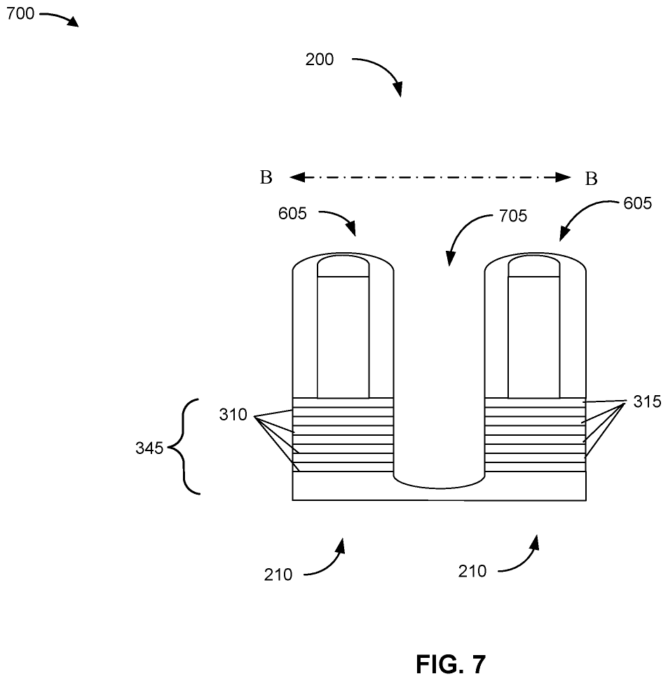

FIG. 7 is a diagram of an example implementation 700 of a source/drain recess formation process described herein. The example implementation 700 includes an example of forming source/drain recesses for the semiconductor device 200. FIG. 7 is illustrated from the perspective of the cross-sectional plane B-B in FIG. 2A. In some implementations, the operations described in connection with the example implementation 700 are performed after the processes described in connection with FIGS. 3A-6.

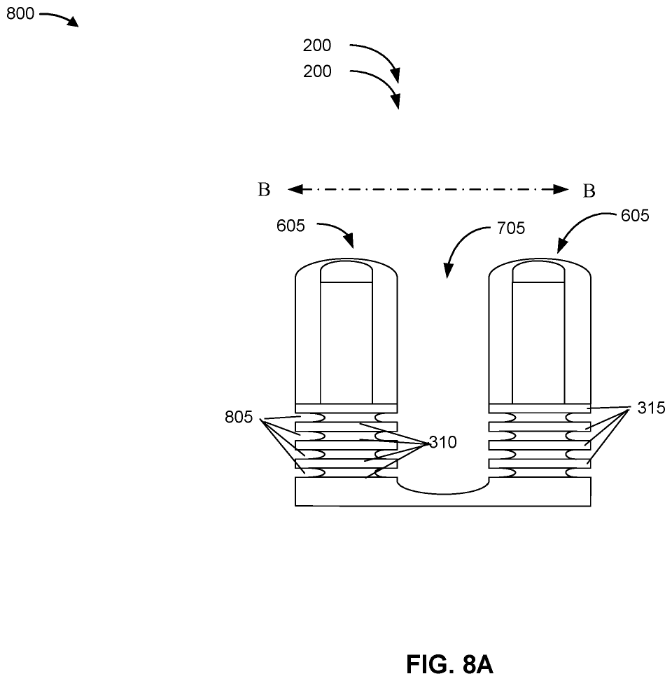

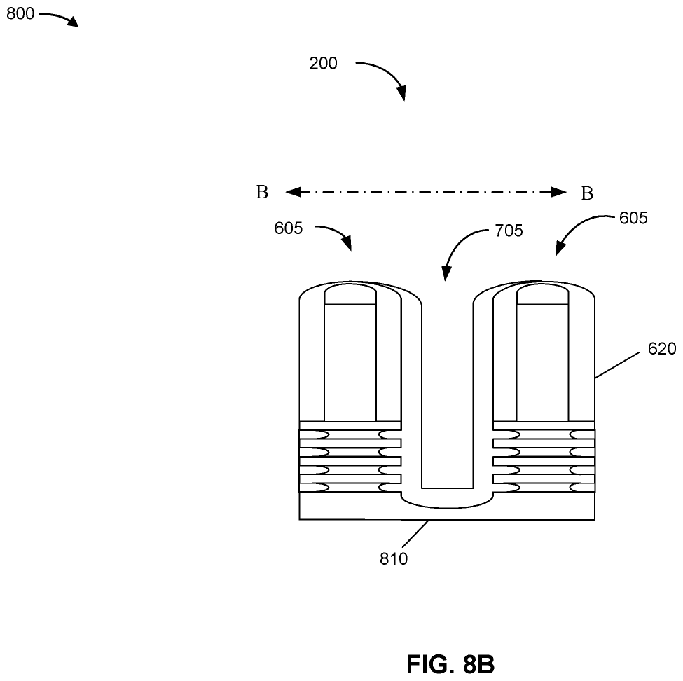

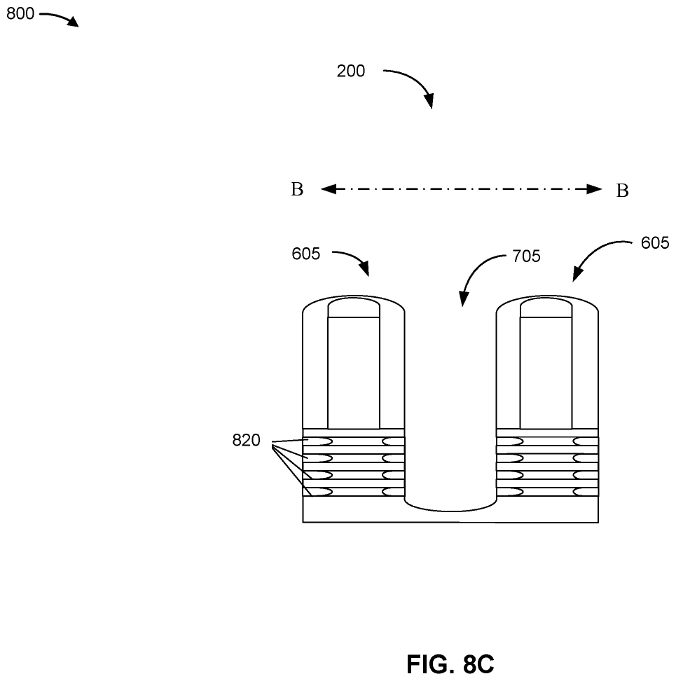

As shown in the cross-sectional plane A-A and cross-sectional plane B-B in FIG. 8A, a source/drain recess 705 is formed in the portions 340 of the fin structure 345 in an etch operation. The source/drain recess 705 are formed to provide spaces in which source/drain regions 225 are to be formed on opposing sides of the dummy gate structures 605. The etch operation may be performed by the etch tool 108 and may be referred to a strained source/drain (SSD) etch operation. In some implementations, the etch operation includes a plasma etch technique, a wet chemical etch technique, and/or another type of etch technique.

The source/drain recess 705 also extend into a portion of the mesa regions 210 of the fin structure 345. This results in the formation of a plurality of mesa regions 210 in each fin structure 345, where sidewalls of the source/drain recess 705 below the dummy gate structures 605 correspond to sidewalls of mesa regions 210. The source/drain recess 705 may penetrate into a well portion (e.g., a p-well, an n-well) of the fin structure 345. In implementations in which the semiconductor substrate 205 includes a silicon (Si) material having a (100) orientation, (111) faces are formed at bottoms of the source/drain recess 705, resulting in formation of a V-shape or a triangular shape cross section at the bottoms of the source/drain recess 705. In some implementations, a wet etching using tetramethylammonium hydroxide (TMAH) and/or a chemical dry etching using hydrochloric acid (HCl) are employed to form the V-shape profile. However, the cross section at the bottoms of the source/drain recess 705 may include other shapes, such as round or semi-circular, among other examples.

As shown in FIG. 7, portions of the first layers 310 and portions of the second layers 315 remain under the dummy gate structures 605 after the etch operation to form the source/drain recess 705. The portions of the second layers 315 under the dummy gate structures 605 form the nanostructure channels 220 of the nanostructure transistors of the semiconductor device 200.

As indicated above, FIG. 7 is provided as an example. Other examples may differ from what is described with regard to FIG. 7. Example implementation 700 may include additional operations, fewer operations, different operations, and/or a different order of operations than those described in connection with FIG. 7.

FIGS. 8A-8C are diagrams of an example implementation of a dummy lateral spacer formation process describe herein. The example implementation 800 includes an example of forming dummy lateral spacers for the semiconductor device 200. FIGS. 8A-8C are illustrated from the perspective of the cross-sectional plane B-B in FIG. 2A. In some implementations, the operations described in connection with the example implementation 800 are performed after the processes described in connection with FIGS. 3A-7.

As shown in the cross-sectional plane B-B in FIG. 8A, the first layers 310 are laterally etched (e.g., in a direction that is approximately parallel to a length of the first layers 310) in an etch operation, thereby forming lateral cavities 805 between portions of the nanostructure channels 220. In other words, the lateral cavities 805 penetrate laterally into the first layers 310 (e.g., penetrate laterally into sacrificial layers). In particular, the etch tool 108 laterally etches ends of the first layers 310 under the dummy gate structures 605 through the source/drain recess 705 to form the lateral cavities 805 between ends of the nanostructure channels 220. In implementations where the first layers 310 are silicon germanium (SiGe) and the second layers 315 are silicon (Si), the etch tool 108 may selectively etch the first layers 310 using a wet etchant such as, a mixed solution including hydrogen peroxide (H₂O₂), acetic acid (CH₃COOH), and/or hydrogen fluoride (HF), followed by cleaning with water (H₂O). The mixed solution and the water may be provided into the source/drain recess 705 to etch the first layers 310 from the source/drain recess 705. In some embodiments, the etching by the mixed solution and cleaning by water is repeated approximately 10 to approximately 20 times. The etching time by the mixed solution is in a range from about 1 minute to about 2 minutes in some implementations. The mixed solution may be used at a temperature in a range of approximately 60º Celsius to approximately 90º Celsius. However, other values for the parameters of the etch operation are within the scope of the present disclosure.

The lateral cavities 805 may be formed to an approximately curved shape, an approximately concave shape, an approximately triangular shape, an approximately square shape, or to another shape. In some implementations, the depth of one or more of the lateral cavities 805 (e.g., the dimension of the cavities extending into the first layers 310 from the source/drain recess 705) is in a range of approximately 1 nanometer to approximately 12 nanometers. However, other values for the depth of the lateral cavities 805 are within the scope of the present disclosure. In some implementations, the etch tool 108 forms the lateral cavities 805 to a length (e.g., the dimension of the cavities extending from a nanostructure channel 220 below a first layer 310 to another nanostructure channel 220 above the first layer 310) such that the lateral cavities 805 partially extend into the sides of the nanostructure channels 220 (e.g., such that the width or length of the lateral cavities 805 are greater than the thickness of the first layers 310). In this way, the inner spacers that are to be formed in the lateral cavities 805 may extend into a portion of the ends of the nanostructure channels 220.

As shown in the cross-sectional plane A-A and in the cross-sectional plane B-B in FIG. 8B, a dummy inner spacer layer 810 is conformally deposited along the bottom and along the sidewalls of the source/drain recess 705. The dummy inner spacer layer 810 may include multiple portions deposited using multiple deposition operations, including a first portion including a first dummy fill material that fills the lateral cavities 805 and a second portion including a second dummy fill material that is over the lateral cavities 805 and adjacent to the dummy sidewall spacer layers 620.

The deposition tool 102 may deposit the dummy inner spacer layer 810 using a CVD technique, a PVD technique, and ALD technique, and/or another deposition technique. In some implementations, the dummy inner spacer layer 810 includes a silicon nitride material (SiₓN_{y}), a silicon oxide material (SiOₓ), a silicon oxynitride material (SiON), a silicon oxycarbide material (SiOC), a silicon carbon nitride material (SiCN), a silicon oxycarbonnitride material (SiOCN), and/or another dielectric material. The dummy inner spacer layer 810 may include one or more materials that are different from the material of dummy sidewall spacer layers 620.

The deposition tool 102 forms the dummy inner spacer layer 810 to a thickness sufficient to fill in the lateral cavities 805 between the nanostructure channels 220 with the dummy inner spacer layer 810. For example, the dummy inner spacer layer 810 may be formed to a thickness in a range of approximately 5 nanometers to approximately 10 nanometers. As another example, the dummy inner spacer layer 810 may be formed to a thickness in a range of approximately 2 nanometers to approximately 5 nanometers. However, other values for the thickness of the dummy inner spacer layer 810 are within the scope of the present disclosure.

As shown in the cross-sectional plane A-A and in the cross-sectional plane B-B in FIG. 8C, a portion of the dummy inner spacer layer 810 removed (e.g., the second portion over the lateral cavities and adjacent to the dummy sidewall spacer layers 620) such that remaining portions of the dummy inner spacer layer 810 correspond to the dummy lateral spacers 820 in the lateral cavities 805. The etch tool 108 may perform an etch operation to partially remove the dummy inner spacer layer 810.

In some implementations, the etch operation may result in the surfaces of the dummy lateral spacers 820 facing the source/drain recess 705 being curved or recessed. The depth of the recesses in the dummy lateral spacers 820 may in a range of approximately 5 nanometers to approximately 12 nanometers, among other examples. In some implementations, the surfaces of the dummy lateral spacers 820 facing the source/drain recess 705 are approximately flat such that the surfaces of the dummy lateral spacers 820 and the surfaces of the ends of the nanostructure channels 220 are approximately even and flush.

As indicated above, FIGS. 8A-8C are provided as examples. Other examples may differ from what is described with regard to FIGS. 8A-8C. Example implementation 800 may include additional operations, fewer operations, different operations, and/or a different order of operations than those described in connection with FIGS. 8A-8C.

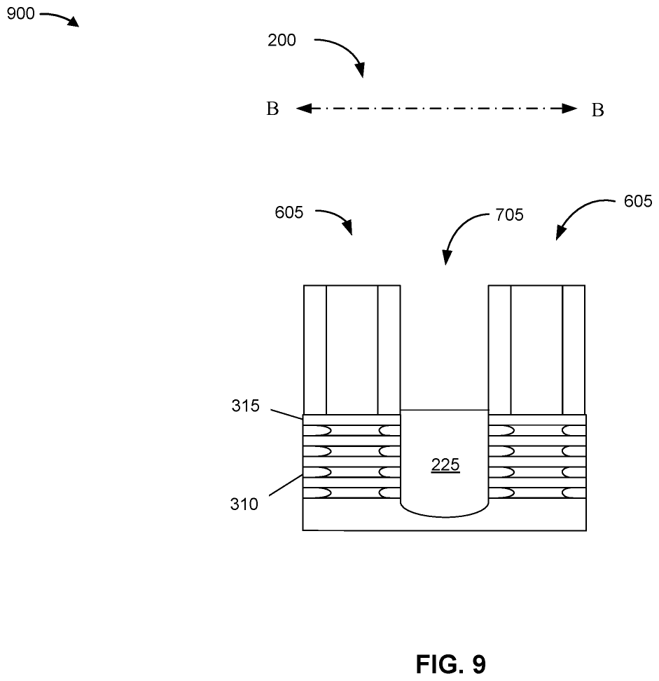

FIG. 9 is a diagram of an example implementation 900 of a source/drain region formation process described herein. The example implementation 900 includes an example of forming the source/drain regions 225 in the source/drain recess 705 for the semiconductor device 200. FIG. 9 is illustrated from the perspective of the cross-sectional plane B-B in FIG. 2A. In some implementations, the operations described in connection with the example implementation 900 are performed after the processes described in connection with FIGS. 3A-8C.

As shown in the cross-sectional plane B-B in FIG. 9, the source/drain recess 705 is filled with one or more layers to form the source/drain region 225 in the source/drain recess 705. For example, the deposition tool 102 may deposit the source/drain regions 225.

The source/drain regions 225 may include one or more layers of epitaxially grown material. For example, the deposition tool 102 may epitaxially grow a first layer of the source/drain regions 225 (referred to as an L1) and may epitaxially grow a second layer of the source/drain region 225 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 200 and to reduce dopant extrusion or migration into the nanostructure channels 220. The second layer may include a highly doped silicon or highly doped silicon germanium. The second layer may be included to provide a compressive stress in the source/drain regions 225 to reduce boron loss.

As indicated above, FIG. 9 is provided as an example. Other examples may differ from what is described with regard to FIG. 9. Example implementation 900 may include additional operations, fewer operations, different operations, and/or a different order of operations than those described in connection with FIG. 9.

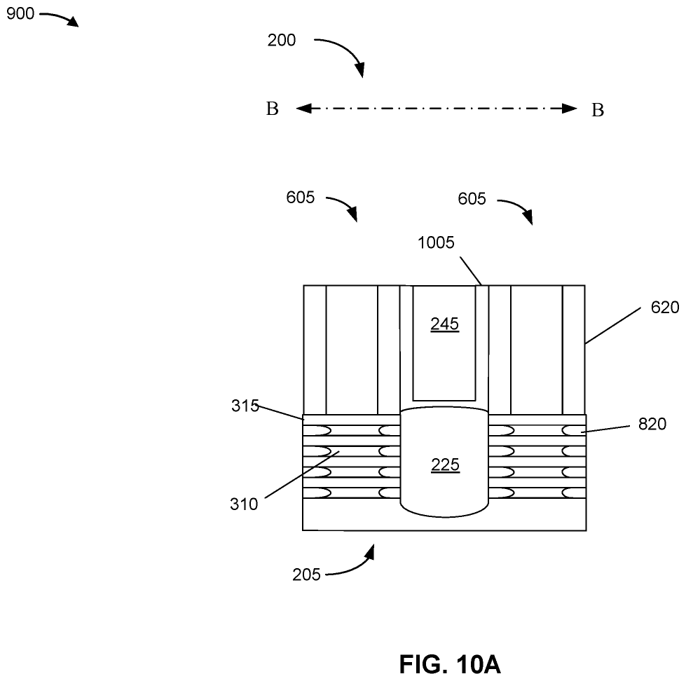

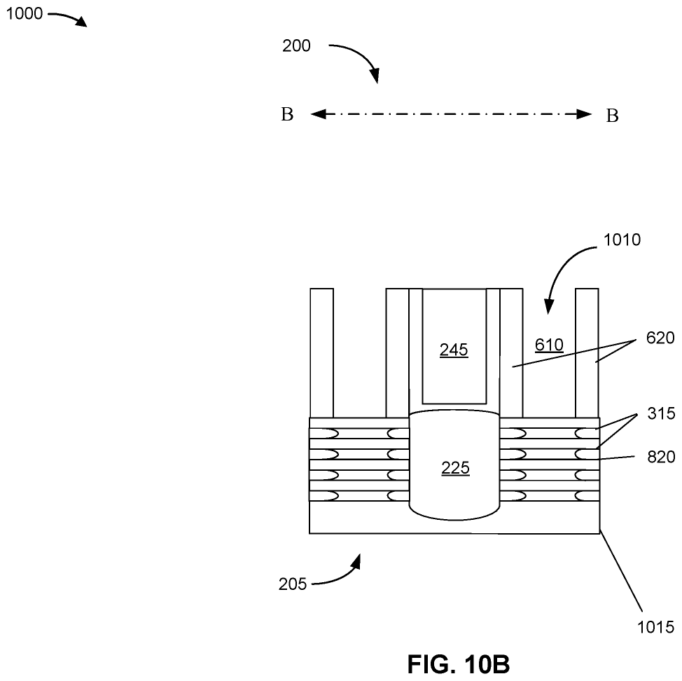

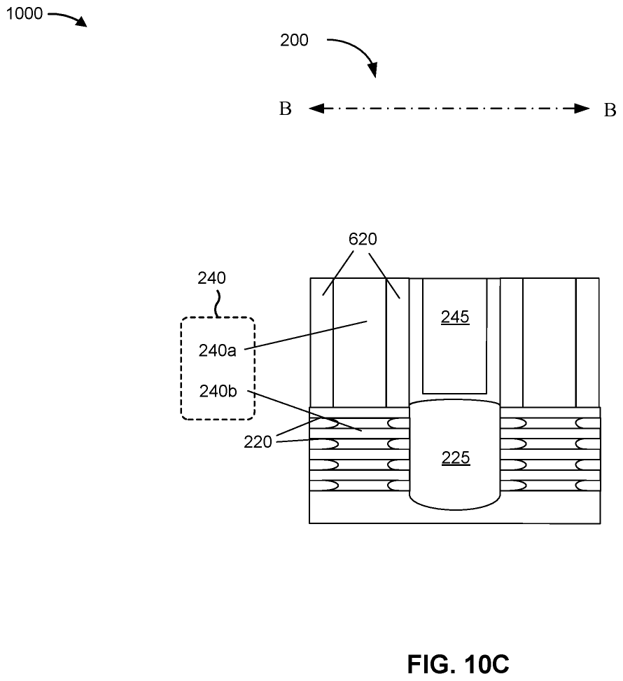

FIGS. 10A-10C are diagrams of an example implementation 1000 of a replacement gate (RPG) process described herein. The example implementation 1000 includes an example of a replacement gate process for replacing the dummy gate structures 605 with the gate structures 240 (e.g., the replacement gate structures) of the semiconductor device 200. Further, the example implementation 1000 includes formation of FIGS. 10A-10C from the perspective of the cross-sectional plane B-B in FIG. 6. In some implementations, the operations described in connection with the example implementation 1000 are performed after the operations described in connection with FIGS. 3A-9. Further, in some figures, some reference numbers and features described in connection with FIGS. 3A-9 may be omitted to avoid obscuring other components or features and for ease of depicting the figures.

As shown in the side view in FIG. 10A, the dielectric layer 245 is formed over the source/drain region 225. The dielectric layer 245 fills in areas between the dummy gate structures 605. The dielectric layer 245 is formed to reduce the likelihood of and/or prevent damage to the source/drain regions 225 during the replacement gate process. The dielectric layer 245 may be referred to as an interlayer dielectric (ILD) zero (ILD0) layer or another ILD layer.

In some implementations, a contact etch stop layer (CESL) 1005 is conformally deposited (e.g., by the deposition tool 102) over the source/drain regions 225, over the dummy gate structures 605, and on the dummy sidewall spacer layers 620 prior to formation of the dielectric layer 245. The dielectric layer 245 is then formed on the CESL 1005. The CESL 1005 may provide a mechanism to stop an etch process when forming contacts or vias for the source/drain regions 225. The CESL 1005 may be formed of a dielectric material having a different etch selectivity from adjacent layers or components. The CESL 1005 may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 1005 may be deposited using a deposition process, such as ALD, CVD, or another deposition technique.

As shown in the side view in FIG. 10B, the replacement gate operation is performed (e.g., by one or more of the semiconductor processing tools 102-112) to remove the dummy gate structures 605 (e.g., including the gate electrode layer 610) from the semiconductor device 200. The removal of the dummy gate structures 605 leaves behind openings (or recesses) 1010 between the dummy sidewall spacer layers 620 and over the source/drain region 225. The dummy gate structures 605 may be removed in one or more etch operations. Such etch operations may include a plasma etch technique, a wet chemical etch technique, and/or another type of etch technique.

The replacement gate operation may further include a nanostructure release operation to remove the first layers 310. This results in openings 1015 between the second layers 315 (e.g., layers from which the nanostructure channels 220 are formed). The nanostructure release operation may include the etch tool 108 performing an etch operation to remove the first layers 310 based on a difference in etch selectivity between the material of the first layers 310 and the material of the second layers 315, and between the material of the first layers 310 and the material of the dummy lateral spacers 820.

In implementations, removal of dummy gate structures 605 and removal of the first layers (e.g., the nanostructure release operations) are performed concurrently (e.g., based on a similarity in materials for the gate electrode layer 610 and the first layers 310, among other examples). In implementations, removal of dummy gate structures 605 and removal of the first layers (e.g., the nanostructure release operations) are performed separately (e.g., based on a difference in materials for the gate electrode layer 610 and the first layers 310, among other examples).

As shown in the side view in FIG. 10C, the replacement gate operation continues where deposition tool 102 and/or the plating tool 112 forms the gate structure 240 (e.g., replacement gate structures). The gate structure 240 includes the lower portion 240b that fills in areas around the nanostructure channels 220 (e.g., fills the openings 1015 between the second layers 315 as shown in FIG. 10B). The lower portion 240b fully wraps around the nanostructure channels 220 and surrounds the nanostructure channels 220. The gate structure 240 further includes the upper portion 240a that fills in areas between the dummy sidewall spacer layers 620 (e.g., fills the openings 1010 between the dummy sidewall spacer layers 620 as shown in FIG. 10B).

The gate structure 240 may include metal gate structures. The gate structure 240 may include additional layers such as an interfacial layer, a high-k dielectric liner layer, a work function tuning layer, and/or a metal electrode structure, among other examples.

As indicated above, the number and arrangement of operations and devices shown in FIGS. 10A-10C are provided as one or more examples. In practice, there may be additional operations and devices, fewer operations and devices, different operations and devices, or differently arranged operations and devices than those shown in FIGS. 10A-10C.

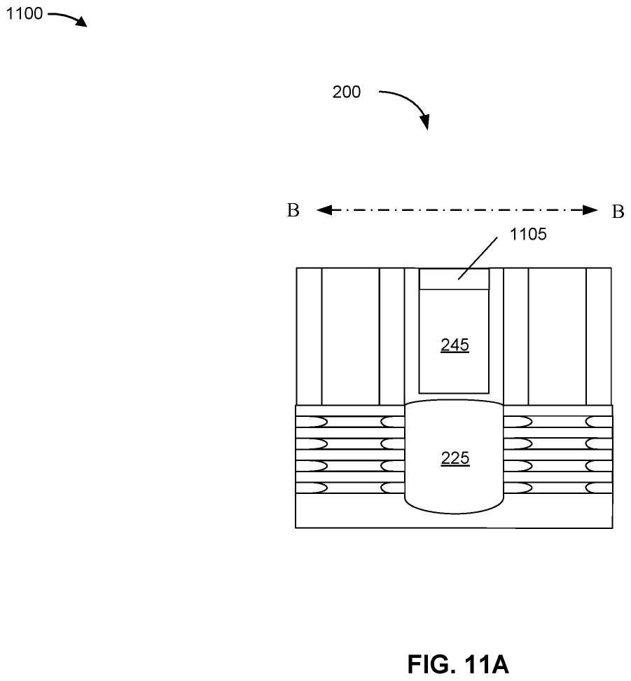

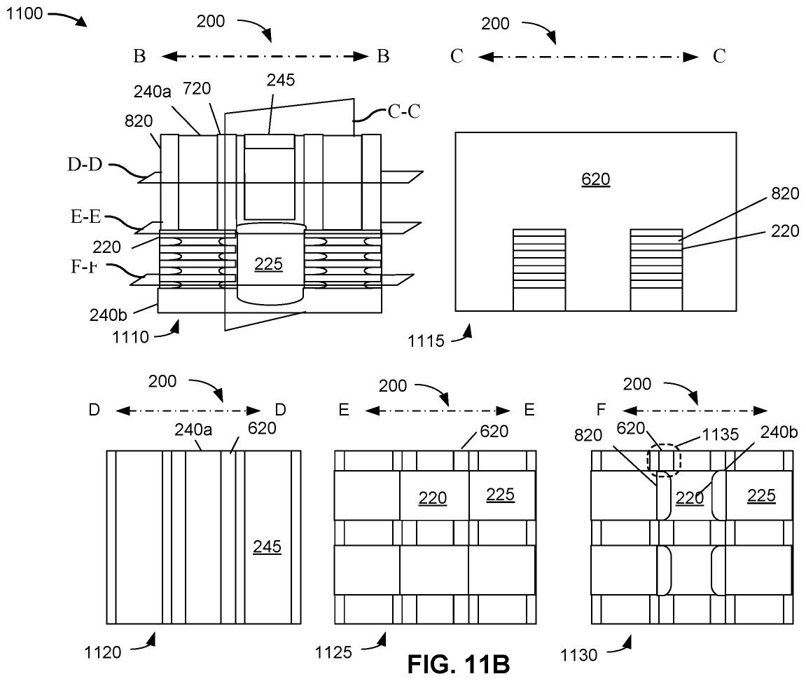

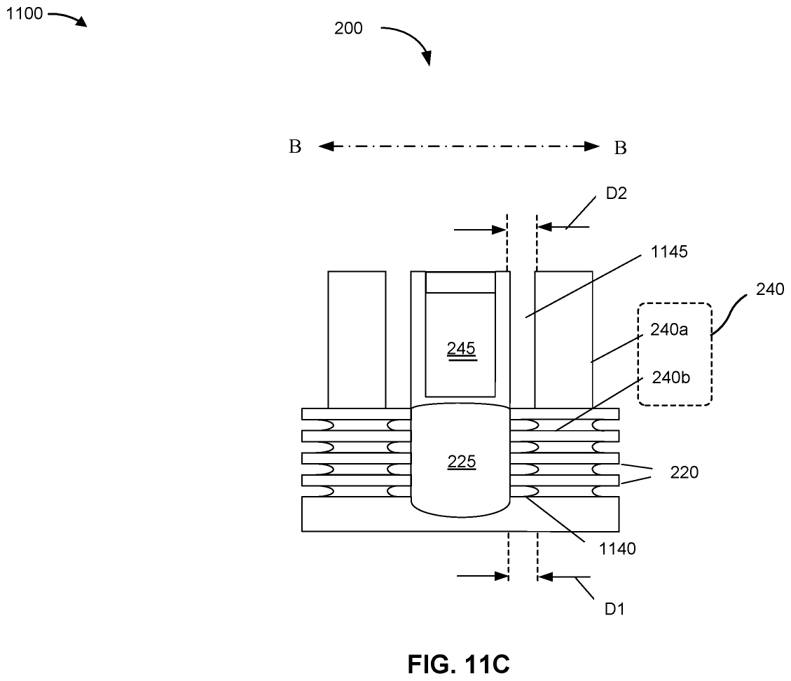

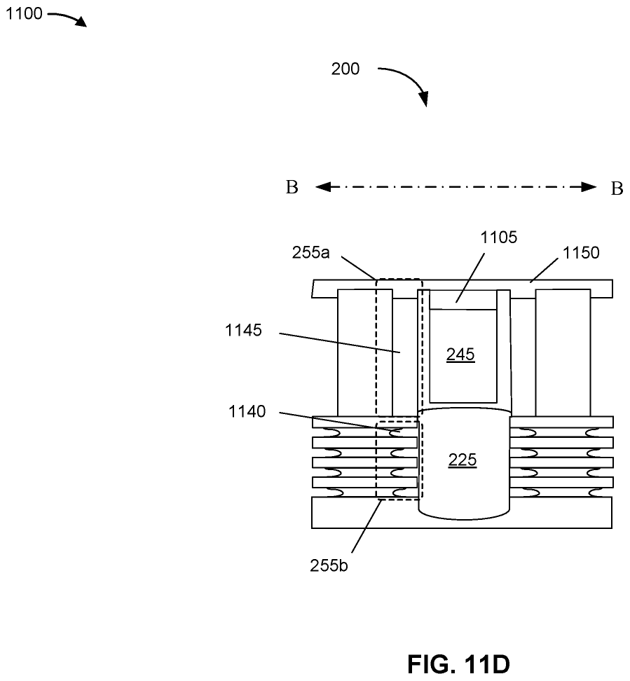

FIGS. 11A-11D are diagrams of an example implementation 1100 of a dielectric region process described herein. As described in connection with FIGS. 11A-11D, the example implementation 1100 includes formation of the upper dielectric region 255a and the lower dielectric region 255b from the perspective of the cross-sectional plane B-B of FIG. 2A. In some implementations, the operations described in connection with the example implementation 1100 are performed after the operations described in connection with FIGS. 3A-10C. Further, in some figures, some reference numbers and features described in connection with FIGS. 3A-10C may be omitted to avoid obscuring other components or features and for ease of depicting the figures.

As shown in the side view of FIG. 11A, a helmet structure 1105 is formed over the dielectric layer 245. For example, the deposition tool 102, the exposure tool 104, the developer tool 106, and/or the etch tool 108, among other examples, may perform as series of operations to form the helmet structure 1105. The helmet structure 1105 may include a silicon nitride (e.g., SiN) material, among other examples. The helmet structure 1105 may protect the dielectric layer 245 during one or more additional operations described in connection with FIGS. 11B and 11C.

The side view 1110 of FIG. 11B (e.g., the cross-sectional plane B-B of the semiconductor device 200) shows additional cross-sectional planes that may be used to describe the formation of dielectric regions within the semiconductor device 200 (e.g., the upper dielectric region 255a and the lower dielectric region 255b).

In connection with the x-y-z coordinate system of FIG. 2A, a cross-sectional plane C-C corresponds to a second x-z plane included in the semiconductor device 200 (e.g., in addition to the cross-sectional plane A-A of the semiconductor device 200). As shown in the side view 1110, the cross-sectional plane C-C passes through the dummy sidewall spacer layers 620 and the dummy lateral spacers 820.

The side view 1115 of FIG. 11B including the cross-sectional plane C-C shows the dummy sidewall spacer layers 620 and the dummy lateral spacers 820 between the second layers 315. During formation of the dielectric regions within the semiconductor device 200, portions of the dummy sidewall spacer layers 620 and portions of the dummy lateral spacers 820, as shown in the side view 1115 of FIG. 11B, are removed.

In connection with the x-y-z coordinate system of FIG. 2A, a cross-sectional plane D-D corresponds to a first x-y plane included in the semiconductor device 200. As shown in the side view 1110, the cross-sectional plane D-D passes through the dummy sidewall spacer layers 620, through the lower portion 240b of the metal gate structure, and through the dielectric layer 245.

The top view 1120 of FIG. 11B including the cross-sectional plane D-D shows the dummy sidewall spacer layers 620, the dielectric layer 245, and the lower portion 240b of the metal gate structure. During formation of the dielectric regions within the semiconductor device 200, portions of the dummy sidewall spacer layers 620 within the cross-sectional plane D-D, as shown in the top view 1120 of FIG. 11B, are removed.

In connection with the x-y-z coordinate system of FIG. 2A, a cross-sectional plane E-E corresponds to a second x-y plane included in the semiconductor device 200. As shown in the side view 1110, the cross-sectional plane E-E passes through a top nanostructure channel of the nanostructure channels 220 and through the source/drain region 225.

The top view 1125 of FIG. 11B including the cross-sectional plane E-E shows the top nanostructure channel of the nanostructure channels 220 and the source/drain region 225. During formation of the dielectric regions within the semiconductor device 200, portions of the dummy sidewall spacer layers 620 in the cross-sectional plane E-E, as shown in the top view 1125 of FIG. 11B, are removed.

In connection with the x-y-z coordinate system of FIG. 2A, a cross-sectional plane F-F corresponds to a third x-y plane included in the semiconductor device 200. As shown in the side view 1110, the cross-sectional plane F-F passes through the upper portion 240a of the metal gate structure, through the dummy lateral spacers 820, and through the source/drain region 225.

The top view 1130 of FIG. 11B including the cross-sectional plane F-F shows the upper portion 240a of the metal gate structure, the dummy lateral spacers 820, and the source/drain region 225. During formation of the dielectric regions within the semiconductor device 200, portions of the dummy sidewall spacer layers 620 within the cross-sectional plane F-F, as shown in the top view 1130 of FIG. 11B, are removed. Removing the portions of the dummy sidewall spacer layers 620 within the cross-sectional plane F-F may begin formation of a tunnel region 1135 within the semiconductor device 200. The tunnel region 1135 may allow for removal of the dummy lateral spacers 820 by an etchant dispersed from above the tunnel region 1135. Additionally, or alternatively, the tunnel region 1135 may connect dielectric regions of the semiconductor device 200 (e.g., the tunnel region 1135 may connect the upper dielectric region 255a and the lower dielectric region 255b, among other examples).

FIG. 11C shows the cross-sectional plane B-B of the semiconductor device 200 after removal of portions of the dummy sidewall spacer layers 620 and/or the dummy lateral spacers 820 as described in connection with FIG. 11B. Removal of the portions of the dummy sidewall spacer layers 620 and/or the dummy lateral spacers 820 may include the etch tool 108 of FIG. 1 performing one or more etch operations to remove portions of the dummy sidewall spacer layers 620 and/or the dummy lateral spacers 820. As an example, the one or more etch operations may include the etch tool 108 performing a dry etch operation using an etchant including an ammonia (NH3) gas, among other examples. If the dummy sidewall spacer layers 620 and the dummy lateral spacers 820 include a same material, such an etching operation may include a single etching operation (e.g., the dummy sidewall spacer layers and the dummy lateral spacers are removed concurrently). Additionally, or alternatively and if the dummy sidewall spacer layers 620 and the dummy lateral spacers 820 include different materials, the etch tool 108 may perform two or more separate etching operations.

As shown in FIG. 11C, removal the dummy lateral spacers 820 may form lateral cavities 1140 (e.g., a plurality of curved regions) penetrating into the gate structure 240 (e.g., the lower portion 240b of the gate structure) between the nanostructure channels 220. Further, and as shown in FIG. 11C, removal of the portions of the dummy sidewall spacer layers 620 may form a vertical cavity 1145 above the lateral cavities 1140 and between the gate structure 240 (e.g., upper portion 240a) and the dielectric layer 245. The etchant that is used in the one or more etch operations may remove the dummy sidewall spacer layers 620 and may propagate downward through the vertical cavities 1145 and the tunnel region 1135 to reach the dummy lateral spacers 820. In this way, the etchant may remove the dummy lateral spacers 820 through the vertical cavities 1145 and the tunnel region 1135 that are formed by removal of the dummy sidewall spacer layers 620.

In some implementations, the lateral cavities 1140 correspond to a size and shape of the lateral cavities 805 of FIG. 8A. In some implementations, the lateral cavities 1140 include a size and shape that is different than the lateral cavities 805 of FIG. 8A (e.g., remnants of the dummy lateral spacers 820 may remain in the lateral cavities 1140 or a width of the lateral cavities 1140 may be adjusted via etching operations to tune a capacitance, among other examples).

In some implementations, a width D1 of the lateral cavities 1140 (e.g., curved regions corresponding to width of the lower dielectric region 255b) may be included in a range of approximately 1 nanometer to approximately 12 nanometers. If the width D1 is less than approximately 1 nanometer, negligible improvements in performance of the semiconductor device 200 (e.g., a reduction in a gate to EPI capacitance (Cᵢₑ) component) may be realized. If the width D1 is greater than approximately 12 nanometers, a junction overlap between the gate structure 240 (including the lower portion 240b) and the source/drain region 225 of the semiconductor device 200 may occur to reduce a performance of the semiconductor device 200. However, other values and ranges for the width D1 are within the scope of the present disclosure.

In some implementations, a width D2 of the vertical cavity 1145 (e.g., corresponding to width of the upper dielectric region 255a) may be included in a range of approximately 1 nanometer to approximately 12 nanometers. If the width D2 is less than approximately 1 nanometer, negligible improvements in performance of the semiconductor device 200 (e.g., a reduction in a gate to contact capacitance (C_{co}) component) may be realized. If the width D2 is greater than approximately 12 nanometers, a junction overlap between the gate structure 240 (including the portion 240b) and the source/drain region 225 of the semiconductor device 200 may occur to reduce a performance of the semiconductor device 200. However, other values and ranges for the width D2 are within the scope of the present disclosure.

FIG. 11D shows formation of the upper dielectric region 255a and the lower dielectric region 255b. As part of forming the upper dielectric region 255a and the lower dielectric region 255b, a gap refill operation may include the deposition tool 102 forming a dielectric layer 1150 over the helmet structure 1105 and over, and/or partially within, the vertical cavity 1145. The dielectric layer 1150 may include a silicon dioxide (SiO₂) material or a silicon nitride (SiN) material, among other examples.

As shown in FIG. 11D, the upper dielectric region 255a includes the vertical cavity 1145, and the lower dielectric region 255b includes the lateral cavities 1140. In some implementations, the upper dielectric region 255a and the lower dielectric region 255b include a same dielectric gas (e.g., air among other examples). In some implementations, the upper dielectric region 255a and the lower dielectric region 255b each include different dielectric gases (e.g., the tunnel region 1135 of FIG. 11B may be plugged prior to formation of the dielectric layer 1150, affording different types of gasses in the upper dielectric region 255a and the lower dielectric region 255b).

After formation of the upper dielectric region 255a and/or the lower dielectric region 255b, a parasitic capacitance of the semiconductor device 200 related to a combination of a gate to top-of-fin capacitance (C_{of}), a gate to substrate inside channel capacitance (C_{if}), a gate to low-doped drain (LDD) overlap capacitance (Cₒᵥ), a gate to contact capacitance (C_{co}), and/or an inner gate to EPI capacitance (Cᵢₑ) may be of a magnitude is less than approximately 10 fF/μm. Such a magnitude may result in a performance of the semiconductor device 200 that is improved relative to another semiconductor device that does not include the upper dielectric region 255a and/or the lower dielectric region 255b.

As indicated above, FIGS. 11A-11D are provided as an example. Other examples may differ from what is described with regard to FIGS. 11A-11D. Example implementation 1100 may include additional operations, fewer operations, different operations, and/or a different order of operations than those described in connection with FIGS. 11A-11D.

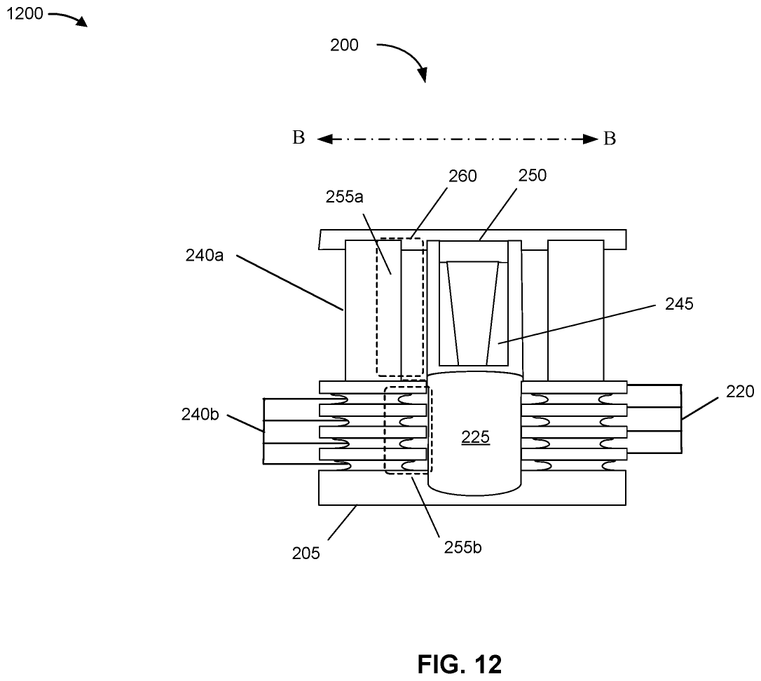

FIG. 12 is a diagram of an example implementation 1200 of a source/drain contact structure process described herein. As described in connection with FIG. 12, the example implementation 1200 includes formation of the contact structure 250 (e.g., a source/drain contact structure or “MD” contact structure, among other examples) from the perspective of the cross-sectional plane B-B of FIG. 6. In some implementations, the operations described in connection with the example implementation 1200 are performed after the operations described in connection with FIGS. 3A-11D. Further, some reference numbers and features described in connection with FIGS. 3A-11D may be omitted to avoid obscuring other components or features and for ease of depicting the figures.

As shown in the side view of FIG. 12, the contact structure 250 is formed in the dielectric layer 245. As an example, a series of operations performed by the deposition tool 102, the exposure tool 104, the developer tool 106, and the etch tool 108 may form the contact structure 250. The contact structure 250 may include, for example, a ruthenium (Ru) material, a tungsten (W) material, or a cobalt (Co) material, among other examples. As shown in FIG. 12, the upper dielectric region 255a is between the upper portion 240a of the metal gate structure and the contact structure 250.

Additionally, or alternatively and as shown in the side view of FIG. 12, the planarization tool 110 may perform a CMP operation to a top surface of the semiconductor device 200 (e.g., the dielectric layer 245). Such a CMP operation may form the filler structure 260.

As indicated above, the number and arrangement of operations and devices shown in FIG. 12 is provided as one or more examples. In practice, there may be additional operations and devices, fewer operations and devices, different operations and devices, or differently arranged operations and devices than those shown in FIG. 12.

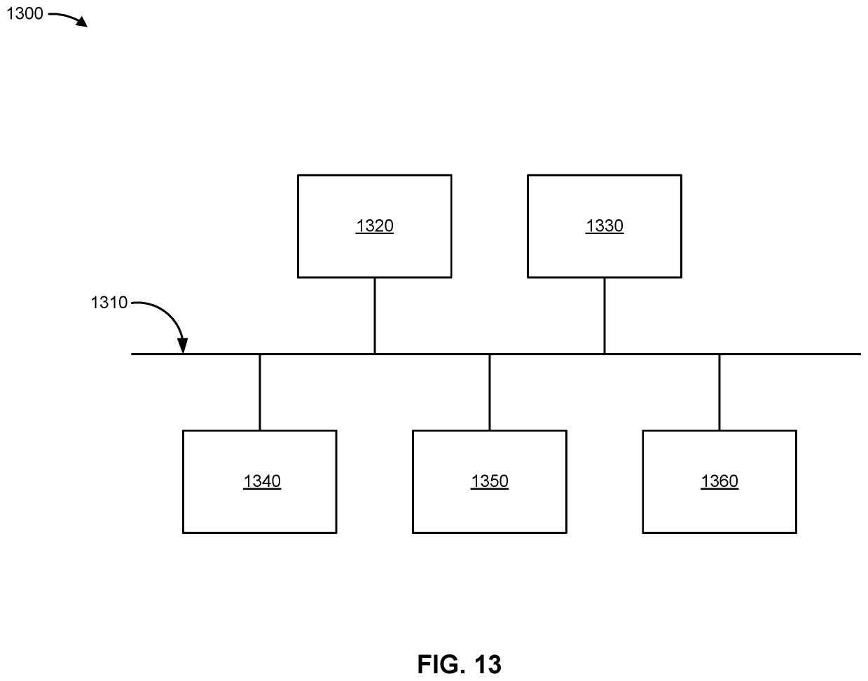

FIG. 13 is a diagram of example components of one or more devices described herein. The device 1300 may correspond to one or more of the semiconductor processing tools 102-112. In some implementations, one or more of the semiconductor processing tools 102-112 may include one or more devices 1300 and/or one or more components of the device 1300. As shown in FIG. 13, the device 1300 may include a bus 1310, a processor 1320, a memory 1330, an input component 1340, an output component 1350, and/or a communication component 1360.

The bus 1310 may include one or more components that enable wired and/or wireless communication among the components of the device 1300. The bus 1310 may couple together two or more components of FIG. 13, such as via operative coupling, communicative coupling, electronic coupling, and/or electric coupling. For example, the bus 1310 may include an electrical connection (e.g., a wire, a trace, and/or a lead) and/or a wireless bus. The processor 1320 may include a central processing unit, a graphics processing unit, a microprocessor, a controller, a microcontroller, a digital signal processor, a field-programmable gate array, an application-specific integrated circuit, and/or another type of processing component. The processor 1320 may be implemented in hardware, firmware, or a combination of hardware and software. In some implementations, the processor 1320 may include one or more processors capable of being programmed to perform one or more operations or processes described elsewhere herein.

The memory 1330 may include volatile and/or nonvolatile memory. For example, the memory 1330 may include random access memory (RAM), read only memory (ROM), a hard disk drive, and/or another type of memory (e.g., a flash memory, a magnetic memory, and/or an optical memory). The memory 1330 may include internal memory (e.g., RAM, ROM, or a hard disk drive) and/or removable memory (e.g., removable via a universal serial bus connection). The memory 1330 may be a non-transitory computer-readable medium. The memory 1330 may store information, one or more instructions, and/or software (e.g., one or more software applications) related to the operation of the device 1300. In some implementations, the memory 1330 may include one or more memories that are coupled (e.g., communicatively coupled) to one or more processors (e.g., processor 1320), such as via the bus 1310. Communicative coupling between a processor 1320 and a memory 1330 may enable the processor 1320 to read and/or process information stored in the memory 1330 and/or to store information in the memory 1330.

The input component 1340 may enable the device 1300 to receive input, such as user input and/or sensed input. For example, the input component 1340 may include a touch screen, a keyboard, a keypad, a mouse, a button, a microphone, a switch, a sensor, a global positioning system sensor, an accelerometer, a gyroscope, and/or an actuator. The output component 1350 may enable the device 1300 to provide output, such as via a display, a speaker, and/or a light-emitting diode. The communication component 1360 may enable the device 1300 to communicate with other devices via a wired connection and/or a wireless connection. For example, the communication component 1360 may include a receiver, a transmitter, a transceiver, a modem, a network interface card, and/or an antenna.

The device 1300 may perform one or more operations or processes described herein. For example, a non-transitory computer-readable medium (e.g., memory 1330) may store a set of instructions (e.g., one or more instructions or code) for execution by the processor 1320. The processor 1320 may execute the set of instructions to perform one or more operations or processes described herein. In some implementations, execution of the set of instructions, by one or more processors 1320, causes the one or more processors 1320 and/or the device 1300 to perform one or more operations or processes described herein. In some implementations, hardwired circuitry may be used instead of or in combination with the instructions to perform one or more operations or processes described herein. Additionally, or alternatively, the processor 1320 may be configured to perform one or more operations or processes described herein. Thus, implementations described herein are not limited to any specific combination of hardware circuitry and software.

The number and arrangement of components shown in FIG. 13 are provided as an example. The device 1300 may include additional components, fewer components, different components, or differently arranged components than those shown in FIG. 13. Additionally, or alternatively, a set of components (e.g., one or more components) of the device 1300 may perform one or more functions described as being performed by another set of components of the device 1300.

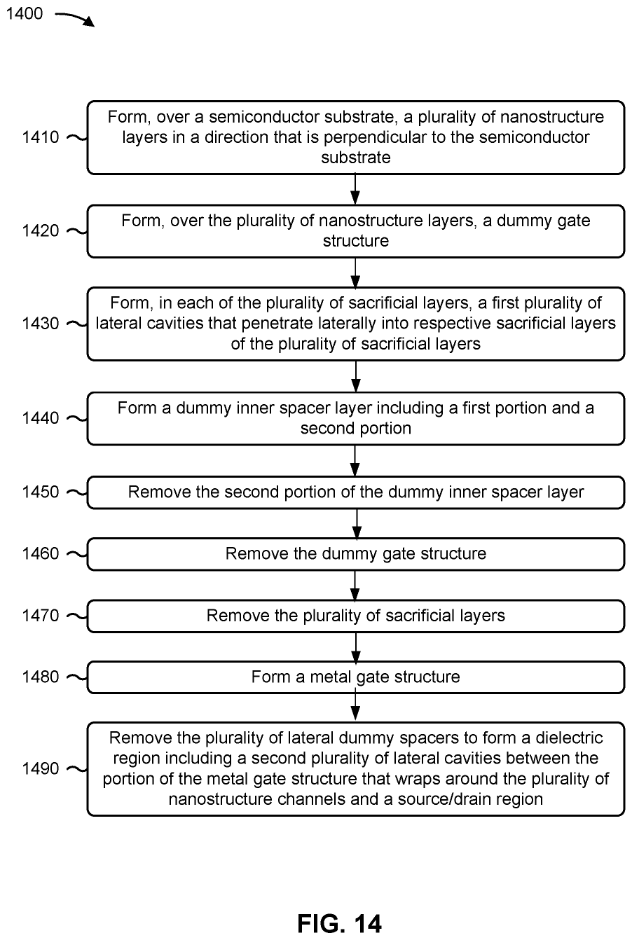

FIG. 14 is a flowchart of an example process 1400 associated with forming the semiconductor device 200 described herein. In some implementations, one or more process blocks of FIG. 14 are performed by one or more of the semiconductor processing tools 102-112. Additionally, or alternatively, one or more process blocks of FIG. 14 may be performed by one or more components of device 1300, such as processor 1320, memory 1330, input component 1340, output component 1350, and/or communication component 1360.

As shown in FIG. 14, process 1400 may include forming, over a semiconductor substrate, a plurality of nanostructure layers in a direction that is perpendicular to the semiconductor substrate (block 1410). For example, the one or more of the semiconductor processing tools 102-112, such as the deposition tool 102, among other examples, may form, over a semiconductor substrate, a plurality of nanostructure layers (e.g., the layer stack 305) in a direction that is perpendicular to the semiconductor substrate 205. In some implementations, the plurality of nanostructure layers comprises a plurality of sacrificial layers (e.g., the first layers 310) alternating with a plurality of channel layers (e.g., the second layers 315).

As further shown in FIG. 14, process 1400 may include forming, over the plurality of nanostructure layers, a dummy gate structure (block 1420). For example, one or more of the semiconductor processing tools 102-112, such as the deposition tool 102, the exposure tool 104, the developer tool 106, and/or the etch tool 108, among other examples, may form, over the plurality of nanostructure layers (e.g., the layer stack 305), a dummy gate structure 605, as described above.

As further shown in FIG. 14, process 1400 may include forming, in the plurality of sacrificial layers, a first plurality of lateral cavities that penetrate laterally into respective sacrificial layers of the plurality of sacrificial layers (block 1430). For example, one or more of the semiconductor processing tools 102-112, such as the etch tool 108, among other examples, may form, in each of the plurality of sacrificial layers (e.g., the first layers 310), a first plurality of lateral cavities (e.g., the lateral cavities 805) that penetrate laterally into respective sacrificial layers of the plurality of sacrificial layers, as described above.

As further shown in FIG. 14, process 1400 may include forming a dummy inner spacer layer including a first portion and a second portion (block 1440). For example, one or more of the semiconductor processing tools 102-112, such as the deposition tool 102, among other examples, may form a dummy inner spacer layer 810 including a first portion and a second portion, as described above. In some implementations, a first portion of the dummy inner spacer layer fills the first plurality of lateral cavities (e.g., the lateral cavities 805).

As further shown in FIG. 14, process 1400 may include removing the second portion of the dummy inner spacer layer (block 1450). For example, one or more of the semiconductor processing tools 102-112, such as the etch tool 108, among other examples, may remove the second portion of the dummy inner spacer layer 810, as described above. In some implementations, the first portion that fills the first plurality of lateral cavities (e.g., the lateral cavities 805) remains in the first plurality of lateral cavities. In some implementations, the first portion that fills the first plurality of lateral cavities corresponds to a plurality of dummy lateral spacers 820 within the first plurality of lateral cavities.

As further shown in FIG. 14, process 1400 may include removing the dummy gate structure (block 1460). For example, one or more of the semiconductor processing tools 102-112, such as the etch tool 108, among other examples, may remove the dummy gate structure 605, as described above.

As further shown in FIG. 14, process 1400 may include removing the plurality of sacrificial layers (block 1470). For example, one or more of the semiconductor processing tools 102-112, such as the etch tool 108, among other examples, may remove the plurality of sacrificial layers (e.g., the first layers 310), as described above.

As further shown in FIG. 14, process 1400 may include forming a metal gate structure (block 1480). For example, one or more of the semiconductor processing tools 102-112, such as the deposition tool 102, among other examples, may form a gate structure 240 as described above. In some implementations, forming the gate structure 240 includes forming a portion (e.g., the lower portion 240b) that wraps around a plurality of nanostructure channels 220 formed from the plurality of channel layers (e.g., the second layers 315).

As further shown in FIG. 14, process 1400 may include removing the plurality of dummy lateral spacers to form a dielectric region including a second plurality of lateral cavities between the portion of the metal gate structure that wraps around the plurality of nanostructure channels and the source/drain region (block 1490). For example, one or more of the semiconductor processing tools 102-112, such as the etch tool 108, among other examples, may remove the plurality of dummy lateral spacers 820 to form a dielectric region (e.g., the lower dielectric region 255b) including a second plurality of lateral cavities (e.g., the lateral cavities 1140) between the portion of the metal gate structure (e.g., the lower portion 240b) that wraps around the plurality of nanostructure channels 220 and a source/drain region 225, as described above.

Process 1400 may include additional implementations, such as any single implementation or any combination of implementations described below and/or in connection with one or more other processes described elsewhere herein.

In a first implementation, process 1400 includes forming a helmet structure 1105 over an dielectric layer 245 that is over the source/drain region 225 subsequent to forming the gate structure 240 and prior to removing the plurality of dummy lateral spacers 820.

In a second implementation, alone or in combination with the first implementation, forming the dummy inner spacer layer 810 includes using a first deposition operation to deposit a first layer of a first dummy fill material corresponding to the first portion that fills the first plurality of lateral cavities (e.g., the lateral cavities 805), and using a second deposition operation that deposits a second layer of a second dummy fill material corresponding to the second portion adjacent to the dummy gate structure 605, where the second dummy fill material is other than the first dummy fill material.

In a third implementation, forming the dummy inner spacer layer 810 includes using a single deposition operation to deposit a single dielectric material.

In a fourth implementation, using the single deposition operation to deposit the single dielectric material comprises using the single deposition operation to deposit a silicon carbon oxynitride material.

In a fifth implementation, the dielectric region (e.g., the dielectric region 255b) corresponds to a first dielectric region, the portion of the metal gate structure (e.g., the lower portion 240b) corresponds to a first portion of the metal gate structure, and the process 1400 further includes removing a portion of a dummy sidewall spacer layer 720 to form a vertical cavity 1145 above the second plurality of lateral cavities (e.g., the lateral cavities 1140), where the vertical cavity 1145 is between a second portion of the metal gate structure (e.g., the upper portion 240a) above the plurality of nanostructure channels 220 and an dielectric layer 245 adjacent to the second portion of the metal gate structure.

In a sixth implementation, removing the portion of the dummy sidewall spacer layer 720 to form the vertical cavity 1145 above the second plurality of lateral cavities (e.g., the lateral cavities 1140) includes removing the portion of the dummy sidewall spacer layer 720 using a removal operation that is concurrent with removing the dummy inner spacer layer 810.

In a seventh implementation, removing portion of the dummy sidewall spacer layer 720 to form the vertical cavity 1145 above the second plurality of lateral cavities (e.g., the lateral cavities 1140) includes removing the portion of the dummy sidewall spacer layer 720 using a removal operation that is separate from another removal operation that removes the dummy inner spacer layer 810.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

Some implementations described herein provide a semiconductor device and methods of formation. The semiconductor device includes a GAA transistor having one or more dielectric regions that include or more dielectric gases. The dielectric regions may include a first dielectric region between epitaxial regions (e.g., source/drain regions) and a first portion of a gate structure of the GAA transistor. The dielectric regions may further include a second dielectric region between a contact structure of GAA transistor and a second portion of the gate structure. By including the dielectric regions in the GAA transistor, a parasitic capacitance associated with the GAA transistor may be reduced relative to another GAA transistor not including the dielectric regions.

In this way, a performance of a semiconductor device including the GAA transistor may improve. By improving the performance of the semiconductor device, the semiconductor device may be compatible with a greater number of applications and/or systems during field use. Additionally, or alternatively, a yield of a volume of semiconductor devices including the GAA transistor may improve to improve a manufacturing efficiency of the volume of semiconductor devices (e.g., a utilization of semiconductor processing tools, a consumption of materials, and/or a utilization of supporting computing resources, among other examples).

As described in greater detail above, some implementations described herein provide a semiconductor device. The semiconductor device includes a plurality of nanostructure channels over a semiconductor substrate, where the plurality of nanostructure channels are arranged in a direction that is perpendicular to the semiconductor substrate. The semiconductor device includes a source/drain region adjacent to the plurality of nanostructure channels. The semiconductor device includes a gate structure. The gate structure includes a first portion over the plurality of nanostructure channels a second portion wrapping around each of the plurality of nanostructure channels. The semiconductor device includes a dielectric region between the second portion of the gate structure and the source/drain region, where the dielectric region includes a dielectric gas.

As described in greater detail above, some implementations described herein provide a semiconductor device. The semiconductor device includes a plurality of nanostructure channels over a semiconductor substrate, where the plurality of nanostructure channels are arranged in a direction that is perpendicular to the semiconductor substrate. The semiconductor device includes a source/drain region adjacent to the plurality of nanostructure channels. The semiconductor device includes a gate structure. The gate structure includes a first portion over the plurality of nanostructure channels a second portion wrapping around each of the plurality of nanostructure channels. The semiconductor device includes a first dielectric region between the first portion of the gate structure and a contact structure adjacent to the first portion of the gate structure, where the first dielectric region includes a first dielectric gas. The semiconductor device includes a second dielectric region between the second portion of the gate structure and the source/drain region, where the second dielectric region includes a second dielectric gas.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As described in greater detail above, some implementations described herein provide a method. The method includes forming, over a semiconductor substrate, a plurality of nanostructure layers in a direction that is perpendicular to the semiconductor substrate, where the plurality of nanostructure layers comprises a plurality of sacrificial layers alternating with a plurality of channel layers. The method includes forming, over the plurality of nanostructure layers, a dummy gate structure. The method includes forming, in each of the plurality of sacrificial layers, a first plurality of lateral cavities that penetrate laterally into respective sacrificial layers of the plurality of sacrificial layers. The method includes forming a dummy inner spacer layer including a first portion and a second portion, where the first portion of the dummy inner spacer layer fills the first plurality of lateral cavities. The method includes removing the second portion of the dummy inner spacer layer, where the first portion that fills the first plurality of lateral cavities remains in the first plurality of lateral cavities, and where the first portion that fills the first plurality of lateral cavities corresponds to a plurality of dummy lateral spacers within the first plurality of lateral cavities. The method includes removing the dummy gate structure. The method includes removing the plurality of sacrificial layers. The method includes forming a metal gate structure, where forming the metal gate structure includes forming a portion that wraps around a plurality of nanostructure channels formed from the plurality of channel layers. The method includes removing the plurality of dummy lateral spacers to form a dielectric region including a second plurality of lateral cavities between the portion of the metal gate structure that wraps around the plurality of nanostructure channels and a source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of nanostructure channels over a semiconductor substrate,
wherein the plurality of nanostructure channels are arranged in a direction that is perpendicular to the semiconductor substrate;
a source/drain region adjacent to the plurality of nanostructure channels;
a gate structure comprising:
a first portion over the plurality of nanostructure channels; and
a second portion wrapping around each of the plurality of nanostructure channels; and
a dielectric region between the second portion of the gate structure and the source/drain region,
wherein the dielectric region comprises a dielectric gas.

2. The semiconductor device of claim 1, wherein the dielectric gas comprises air.

3. The semiconductor device of claim 1, wherein the dielectric region includes a plurality of curved regions penetrating into the second portion of the gate structure between the plurality of nanostructure channels.

4. The semiconductor device of claim 3, wherein each of the plurality of curved regions includes a width that is included in a range of approximately 1 nanometer to approximately 12 nanometers.

5. The semiconductor device of claim 3, wherein the dielectric region corresponds to a first dielectric region; and
wherein the semiconductor device further comprises:
a second dielectric region comprising the dielectric gas,
wherein the second dielectric region is above the first dielectric region, and
wherein the second dielectric region is between a contact structure and the first portion of the gate structure.

6. The semiconductor device of claim 5, wherein a width of the second dielectric region is included in a range of approximately 1 nanometer to approximately 12 nanometers.

7. A semiconductor device, comprising:
a plurality of nanostructure channels over a semiconductor substrate,
wherein the plurality of nanostructure channels are arranged in a direction that is perpendicular to the semiconductor substrate;
a source/drain region adjacent to the plurality of nanostructure channels;
a gate structure comprising:
a first portion over the plurality of nanostructure channels; and
a second portion wrapping around each of the plurality of nanostructure channels;
a first dielectric region between the first portion of the gate structure and a contact structure adjacent to the first portion of the gate structure,
wherein the first dielectric region comprises a first dielectric gas; and
a second dielectric region between the second portion of the gate structure and the source/drain region,
wherein the second dielectric region comprises a second dielectric gas.

8. The semiconductor device of claim 7, wherein the first dielectric gas and the second dielectric gas comprise a same dielectric gas.

9. The semiconductor device of claim 7, wherein the first dielectric gas and the second dielectric gas comprise different dielectric gases.

10. The semiconductor device of claim 7, wherein a top nanostructure channel of the plurality of nanostructure channels is between the first dielectric region and the second dielectric region.

11. The semiconductor device of claim 7, further comprising:
a filler structure above the first dielectric region and above the second dielectric region,
wherein the filler structure is configured to seal the second dielectric gas within the second dielectric region.

12. The semiconductor device of claim 7, further comprising:
a tunnel region that connects the first dielectric region and the second dielectric region.

13. A method, comprising:
forming, over a semiconductor substrate, a plurality of nanostructure layers in a direction that is perpendicular to the semiconductor substrate,
wherein the plurality of nanostructure layers comprises a plurality of sacrificial layers alternating with a plurality of channel layers;
forming, over the plurality of nanostructure layers, a dummy gate structure;
forming, in each of the plurality of sacrificial layers, a first plurality of lateral cavities that penetrate laterally into respective sacrificial layers of the plurality of sacrificial layers;
forming a dummy inner spacer layer including a first portion and a second portion,
wherein the first portion of the dummy inner spacer layer fills the first plurality of lateral cavities;
removing the second portion of the dummy inner spacer layer,
wherein the first portion that fills the first plurality of lateral cavities remains in the first plurality of lateral cavities, and
wherein the first portion that fills the first plurality of lateral cavities corresponds to a plurality of dummy lateral spacers within the first plurality of lateral cavities;
removing the dummy gate structure;
removing the plurality of sacrificial layers;
forming a metal gate structure,
wherein forming the metal gate structure comprises forming a portion that wraps around a plurality of nanostructure channels formed from the plurality of channel layers; and
removing the plurality of dummy lateral spacers to form a dielectric region including a second plurality of lateral cavities between the portion of the metal gate structure that wraps around the plurality of nanostructure channels and a source/drain region.

14. The method of claim 13, further comprising:
forming a helmet structure over a dielectric layer that is over the source/drain region subsequent to forming the metal gate structure and prior to removing the plurality of dummy lateral spacers.

15. The method of claim 13, wherein forming the dummy inner spacer layer comprises:
using a first deposition operation to deposit a first layer of a first dummy fill material corresponding to the first portion that fills the first plurality of lateral cavities; and
using a second deposition operation that deposits a second layer of a second dummy fill material corresponding to the second portion adjacent to the dummy gate structure,
wherein the second dummy fill material is other than the first dummy fill material.

16. The method of claim 13, wherein forming the dummy inner spacer layer comprises:
using a single deposition operation to deposit a single dielectric material.

17. The method of claim 16, wherein using the single deposition operation to deposit the single dielectric material comprises:
using the single deposition operation to deposit a silicon oxycarbonnitride material.

18. The method of claim 13, wherein the dielectric region corresponds to a first dielectric region, the portion of the metal gate structure corresponds to a first portion of the metal gate structure, and further comprising:
removing a portion of a dummy sidewall spacer layer to form a vertical cavity above the second plurality of lateral cavities,
wherein the vertical cavity is between a second portion of the metal gate structure above the plurality of nanostructure channels and a dielectric layer adjacent to the second portion of the metal gate structure.

19. The method of claim 18, wherein removing the portion of the dummy sidewall spacer layer to form the vertical cavity above the second plurality of lateral cavities comprises:
removing the portion of the dummy sidewall spacer layer using a removal operation that is concurrent with removing the dummy inner spacer layer.

20. The method of claim 18, wherein removing portion of the dummy sidewall spacer layer to form the vertical cavity above the second plurality of lateral cavities comprises:
removing the portion of the dummy sidewall spacer layer using a removal operation that is separate from another removal operation that removes the dummy inner spacer layer.
